(19) United States
(12) Patent Application Publication
(10) Pub. No.: US 2026/0330086 A1
(43) Pub. Date: Oct. 22, 2026

(54) SYSTEMS, APPARATUSES, METHODS, AND COMPUTER PROGRAM PRODUCTS FOR GENERATING A NEW PHYSICAL COMPONENT

(71) Applicant: Honeywell International Inc., Charlotte, NC (US)

(72) Inventors: Honey RAGHAVAN, Bangalore (IN); Anil PALLAYIL, Charlotte, NC (US); Rahul SHARMA, Houston, TX (US)

(21) Appl. No.: 19/650,491

(22) Filed: Apr. 17, 2026

Related U.S. Application Data
(60) Provisional application No. 63/790,875, filed on Apr. 18, 2025.

(51) Int. Cl. G06F 30/17; G06Q 10/0875; G06Q 10/10

(52) U.S. Cl. CPC G06F 30/17; G06Q 10/0875; G06Q 10/103

(57) ABSTRACT

Systems, apparatuses, methods, and computer program products are provided herein. For example, a method may include accessing a requirement electronic record. In some embodiments, the method comprises retrieving, by a project component engineering predictive computing entity, a set of archived physical component objects. In some embodiments, the method comprises generating, using the project component engineering predictive computing entity, a physical component requirement indication by applying the requirement electronic record and the set of archived physical component objects to a component differentiation model. In some embodiments, the method comprises generating, using the project component engineering predictive computing entity and based on the physical component generation indicator, a new physical component object. In some embodiments, the method comprises extracting a set of new physical component features. In some embodiments, the method comprises causing, using the project orchestration predictive computing entity, performance of one or more new physical component responsive actions.

### CROSS-REFERENCE TO RELATED APPLICATIONS

This nonprovisional application claims the benefit of priority to U.S. Provisional Patent Application No. 63/790,875, filed Apr. 18, 2025, entitled “SYSTEMS, APPARATUSES, METHODS, AND COMPUTER PROGRAM PRODUCTS FOR GENERATING A NEW PHYSICAL COMPONENT,” the entire contents of which are hereby incorporated by reference for all purposes pursuant to 35 U.S.C. § 119(e).

### TECHNOLOGICAL FIELD

Embodiments of the present disclosure relate generally to systems, apparatuses, methods, and computer program products for generating a new physical component.

### BACKGROUND

Applicant has identified many technical challenges and difficulties associated with systems, apparatuses, methods, and computer program products for generating a new physical component. Through applied effort, ingenuity, and innovation, Applicant has solved problems related to systems, apparatuses, methods, and computer program products for generating a new physical component by developing solutions embodied in the present disclosure, which are described in detail below.

### BRIEF SUMMARY

Various embodiments described herein relate to systems, apparatuses, methods, and computer program products for generating a new physical component.

In accordance with one aspect of the disclosure a method is provided. In some embodiments, the method comprises accessing, at a project orchestration predictive computing entity, a requirement electronic record, wherein the requirement electronic record is representative of a physical component feature, retrieving, by a project component engineering predictive computing entity, a set of archived physical component objects from an archived physical component database, generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator, generating, using the project component engineering predictive computing entity and based on the physical component generation indicator, a new physical component object, extracting, using the project component engineering predictive computing entity, a set of new physical component features from the new physical component object, and causing, using the project orchestration predictive computing entity, performance of one or more new physical component responsive actions based on at least one of the set of new physical component features.

In some embodiments, the method further comprises generating, based on the physical component reconfiguration indicator, a reconfigured physical component object, wherein the reconfigured physical component object corresponds to an archived physical component object of the set of archived physical component objects, extracting a set of reconfigured physical component features from the reconfigured physical component object, and causing performance of one or more reconfigured physical component responsive actions based on at least one of the set of reconfigured physical component features.

In some embodiments, the new physical component object comprises a 3-dimensional virtual model.

In some embodiments, the method further comprises storing the new physical component object in the archived physical component database, accessing an additional requirement electronic record, wherein the additional requirement electronic record is representative of an additional physical component feature, retrieving a revised set of archived physical component objects from the archived physical component database, wherein the revised set of archived physical component objects comprises the new physical component object, and generating an additional physical component requirement indication by applying the additional requirement electronic record and the revised set of archived physical component objects to the component differentiation model, wherein the additional physical component requirement indication comprises an additional physical component generation indicator, an additional physical component reconfiguration indicator, or a physical component reusable indicator.

In some embodiments, the method further comprises generating, based on the physical component reusable indicator, an additional project electronic record, wherein the additional project electronic record comprises the new physical component object.

In some embodiments, the method further comprises generating, based on the physical component reconfiguration indicator, an additional project electronic record, wherein the additional project electronic record comprises an additional reconfigured physical component object.

In some embodiments, the method further comprises generating a project electronic record, wherein the project electronic record comprises the new physical component object.

In some embodiments, the method further comprises generating, a project electronic record interface component, wherein the project electronic record interface component comprises a visual representation of the project electronic record and causing rendering of the project electronic record interface component via a responsive action interface.

In some embodiments, the method further comprises causing a component inventory record to be updated.

In some embodiments, the method further comprises transmitting the project electronic record to a project foundation device.

In accordance with another aspect of the disclosure, an apparatus is provided. In some embodiments, the apparatus includes memory and one or more processors communicatively coupled to the memory. In some embodiments, the one or more processors are configured to perform operations comprising accessing, at a project orchestration predictive computing entity, a requirement electronic record, wherein the requirement electronic record is representative of a physical component feature, retrieving, by a project component engineering predictive computing entity, a set of archived physical component objects from an archived physical component database, generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator, generating, using the project component engineering predictive computing entity and based on the physical component generation indicator, a new physical component object, extracting, using the project component engineering predictive computing entity, a set of new physical component features from the new physical component object, and causing, using the project orchestration predictive computing entity, performance of one or more new physical component responsive actions based on at least one of the set of new physical component features.

In some embodiments, the one or more processors are further configured to perform operations comprising generating, based on the physical component reconfiguration indicator, a reconfigured physical component object, wherein the reconfigured physical component object corresponds to an archived physical component object of the set of archived physical component objects, extracting a set of reconfigured physical component features from the reconfigured physical component object, and causing performance of one or more reconfigured physical component responsive actions based on at least one of the set of reconfigured physical component features.

In some embodiments, the new physical component object comprises a 3-dimensional virtual model.

In some embodiments, the one or more processors are further configured to perform operations comprising storing the new physical component object in the archived physical component database, accessing an additional requirement electronic record, wherein the additional requirement electronic record is representative of an additional physical component feature, retrieving a revised set of archived physical component objects from the archived physical component database, wherein the revised set of archived physical component objects comprises the new physical component object, and generating an additional physical component requirement indication by applying the additional requirement electronic record and the revised set of archived physical component objects to the component differentiation model, wherein the additional physical component requirement indication comprises an additional physical component generation indicator, an additional physical component reconfiguration indicator, or a physical component reusable indicator.

In some embodiments, the one or more processors are further configured to perform operations comprising generating, based on the physical component reusable indicator, an additional project electronic record, wherein the additional project electronic record comprises the new physical component object.

In some embodiments, the one or more processors are further configured to perform operations comprising generating, based on the physical component reconfiguration indicator, an additional project electronic record, wherein the additional project electronic record comprises an additional reconfigured physical component object.

In some embodiments, the one or more processors are further configured to perform operations comprising generating a project electronic record, wherein the project electronic record comprises the new physical component object.

In some embodiments, the one or more processors are further configured to perform operations comprising generating, a project electronic record interface component, wherein the project electronic record interface component comprises a visual representation of the project electronic record and causing rendering of the project electronic record interface component via a responsive action interface.

In some embodiments, the one or more processors are further configured to perform operations comprising causing a component inventory record to be updated.

In some embodiments, the one or more processors are further configured to perform operations comprising transmitting the project electronic record to a project foundation device.

In accordance with another aspect of the disclosure, a computer program product is provided. In some embodiments, the computer program product includes at least one non-transitory computer-readable storage medium having computer program code stored thereon. In some embodiments, the computer program code, in execution with at least one processor, configures the computer program product for accessing, at a project orchestration predictive computing entity, a requirement electronic record, wherein the requirement electronic record is representative of a physical component feature, retrieving, by a project component engineering predictive computing entity, a set of archived physical component objects from an archived physical component database, generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator, generating, using the project component engineering predictive computing entity and based on the physical component generation indicator, a new physical component object, extracting, using the project component engineering predictive computing entity, a set of new physical component features from the new physical component object, and causing, using the project orchestration predictive computing entity, performance of one or more new physical component responsive actions based on at least one of the set of new physical component features.

In some embodiments, the computer program code, in execution with at least one processor, further configures the computer program product for generating, based on the physical component reconfiguration indicator, a reconfigured physical component object, wherein the reconfigured physical component object corresponds to an archived physical component object of the set of archived physical component objects, extracting a set of reconfigured physical component features from the reconfigured physical component object, and causing performance of one or more reconfigured physical component responsive actions based on at least one of the set of reconfigured physical component features.

In some embodiments, the new physical component object comprises a 3-dimensional virtual model.

In some embodiments, the computer program code, in execution with at least one processor, further configures the computer program product for storing the new physical component object in the archived physical component database, accessing an additional requirement electronic record, wherein the additional requirement electronic record is representative of an additional physical component feature, retrieving a revised set of archived physical component objects from the archived physical component database, wherein the revised set of archived physical component objects comprises the new physical component object, and generating an additional physical component requirement indication by applying the additional requirement electronic record and the revised set of archived physical component objects to the component differentiation model, wherein the additional physical component requirement indication comprises an additional physical component generation indicator, an additional physical component reconfiguration indicator, or a physical component reusable indicator.

In some embodiments, the computer program code, in execution with at least one processor, further configures the computer program product for generating, based on the physical component reusable indicator, an additional project electronic record, wherein the additional project electronic record comprises the new physical component object.

In some embodiments, the computer program code, in execution with at least one processor, further configures the computer program product for generating, based on the physical component reconfiguration indicator, an additional project electronic record, wherein the additional project electronic record comprises an additional reconfigured physical component object.

In some embodiments, the computer program code, in execution with at least one processor, further configures the computer program product for generating a project electronic record, wherein the project electronic record comprises the new physical component object.

In some embodiments, the computer program code, in execution with at least one processor, further configures the computer program product for generating, a project electronic record interface component, wherein the project electronic record interface component comprises a visual representation of the project electronic record and causing rendering of the project electronic record interface component via a responsive action interface.

In some embodiments, the computer program code, in execution with at least one processor, further configures the computer program product for causing a component inventory record to be updated.

In some embodiments, the computer program code, in execution with at least one processor, further configures the computer program product for transmitting the project electronic record to a project foundation device.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an example block diagram of an environment in which embodiments of the present disclosure may operate;

FIG. 2 illustrates an example block diagram of the environment in which embodiments of the present disclosure may operate;

FIG. 3 illustrates an example block diagram of an example apparatus that may be specially configured in accordance with an example embodiment of the present disclosure;

FIG. 4 illustrates an example data flow in accordance with one or more embodiments of the present disclosure;

FIG. 5 illustrates another example data flow in accordance with one or more embodiments of the present disclosure;

FIG. 6 illustrates an example interface component in accordance with one or more embodiments of the present disclosure;

FIG. 7 illustrates a flowchart of an example method in accordance with one or more embodiments of the present disclosure;

FIG. 8 illustrates a flowchart of an example method in accordance with one or more embodiments of the present disclosure;

FIG. 9 illustrates a flowchart of an example method in accordance with one or more embodiments of the present disclosure; and

FIG. 10 illustrates a flowchart of an example method in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

The use of the term “circuitry” as used herein with respect to components of a system, or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communication circuitry, input/output circuitry, and the like. In some embodiments, other elements may provide or supplement the functionality of particular circuitry. Alternatively, or additionally, in some embodiments, other elements of a system and/or apparatus described herein may provide or supplement the functionality of another particular set of circuitry. For example, a processor may provide processing functionality to any of the sets of circuitry, a memory may provide storage functionality to any of the sets of circuitry, communications circuitry may provide network interface functionality to any of the sets of circuitry, and/or the like.

### Overview

Example embodiments disclosed herein address technical problems associated with systems, apparatuses, methods, and computer program products for generating a new physical component. As would be understood by one skilled in the field to which this disclosure pertains, there are numerous example scenarios in which systems, apparatuses, methods, and computer program products for generating a new physical component. For example, it may be desirable to use systems, apparatuses, methods, and computer program products for generating a new physical component to be used in a project.

Example solutions for generating a new physical component include using computing devices to implement new physical component generation. However, such example solutions are simplistic, inefficient, and reactive. For example, such example solutions are simplistic because such example solutions do not implement a plurality of predictive computing entities to execute discrete tasks using generative artificial intelligence. As another example, such example solutions are inefficient because such example solutions do not leverage archived physical component objects identified via a component differentiation model for new physical component generation. As another example, such example solutions are reactive because such example solutions do not automatically implement new physical component responsive actions based on new physical component features and/or project electronic records. Accordingly, there is a need for systems, apparatuses, methods, and computer program products that perform new physical component generation in a sophisticated, efficient, and proactive manner.

Thus, to address these and/or other issues related to such example solutions, example systems, apparatuses, methods, and computer program products for new physical component generation are disclosed herein. For example, an embodiment in this disclosure, described in greater detail below, includes a method that includes accessing, at a project orchestration predictive computing entity, a requirement electronic record. In some embodiments, the requirement electronic record is representative of a physical component feature. In some embodiments, the method comprises retrieving, by a project component engineering predictive computing entity, a set of archived physical component objects from an archived physical component database. In some embodiments, the method comprises generating, using the project component engineering predictive computing entity, a physical component requirement indication by applying the requirement electronic record and the set of archived physical component objects to a component differentiation model. In some embodiments, the physical component requirement indication comprises a physical component generation indicator or a physical component reconfiguration indicator. In some embodiments, the method comprises generating, using the project component engineering predictive computing entity and based on the physical component generation indicator, a new physical component object. In some embodiments, the method comprises extracting, using the project component engineering predictive computing entity, a set of new physical component features from the new physical component object. In some embodiments, the method comprises causing, using the project orchestration predictive computing entity, performance of one or more new physical component responsive actions based on at least one of the set of new physical component features.

Further embodiments and advantages of the example systems, apparatuses, methods, and computer program products disclosed herein are described in the following co-pending U.S. patent applications: U.S. Application No. 63/790,880, titled “SYSTEMS, APPARATUSES, METHODS, AND COMPUTER PROGRAM PRODUCTS FOR AUTOMATED PROJECT OPERATIONS ARCHITECTURE”; U.S. Application No. 63/790,876, titled “SYSTEMS, APPARATUSES, METHODS, AND COMPUTER PROGRAM PRODUCTS FOR AN INTERACTIVE PROJECT REQUIREMENTS ANALYSIS ENGINE”; U.S. Application No. 63/790,873, titled “SYSTEMS, APPARATUSES, METHODS, AND COMPUTER PROGRAM PRODUCTS FOR A PROJECT OUTCOME PREDICTIVE ENGINE”; U.S. Application No. 63/790,878, titled “SYSTEMS, APPARATUSES, METHODS, AND COMPUTER PROGRAM PRODUCTS FOR NEW PROJECT GENERATION”; U.S. Application No. 63/790,882, titled “SYSTEMS, APPARATUSES, METHODS, AND COMPUTER PROGRAM PRODUCTS FOR REAL-TIME PROJECT INVENTORY OPTIMIZATION”; U.S. Application No. 63/790,885, titled “SYSTEMS, APPARATUSES, METHODS, AND COMPUTER PROGRAM PRODUCTS FOR REAL-TIME PROJECT SERVICES OPERATIONS”; U.S. Application No. 63/790,889, titled “SYSTEMS, APPARATUSES, METHODS, AND COMPUTER PROGRAM PRODUCTS FOR PROJECT PROGRAM GENERATION”; U.S. Application No. 63/790,892, titled “SYSTEMS, APPARATUSES, METHODS, AND COMPUTER PROGRAM PRODUCTS FOR AUTOMATED PROJECT QUALITY CONTROL”; U.S. Application No. 63/790,879, titled “SYSTEMS, APPARATUSES, METHODS, AND COMPUTER PROGRAM PRODUCTS FOR AI DRIVEN PROJECT COMPLIANCE FORECASTING”, each of which is filed concurrently with the present application. The contents of each of the foregoing applications are hereby incorporated by reference in their entirety.

### Example Systems and Apparatuses

Embodiments of the present disclosure herein include systems, apparatuses, methods, and computer program products configured for new physical component generation. It should be readily appreciated that the embodiments of the apparatus, systems, methods, and computer program product described herein may be configured in various additional and alternative manners in addition to those expressly described herein.

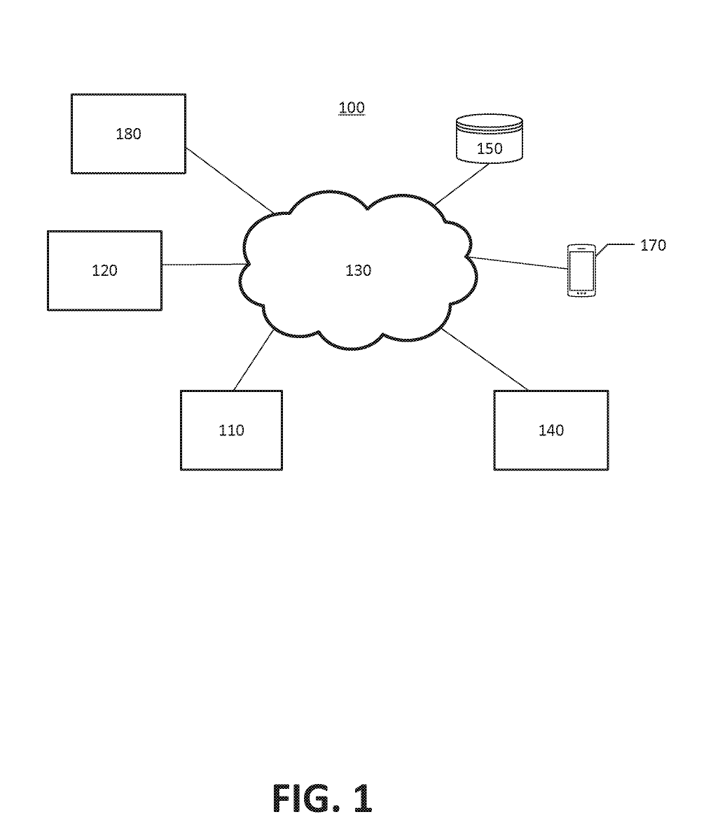

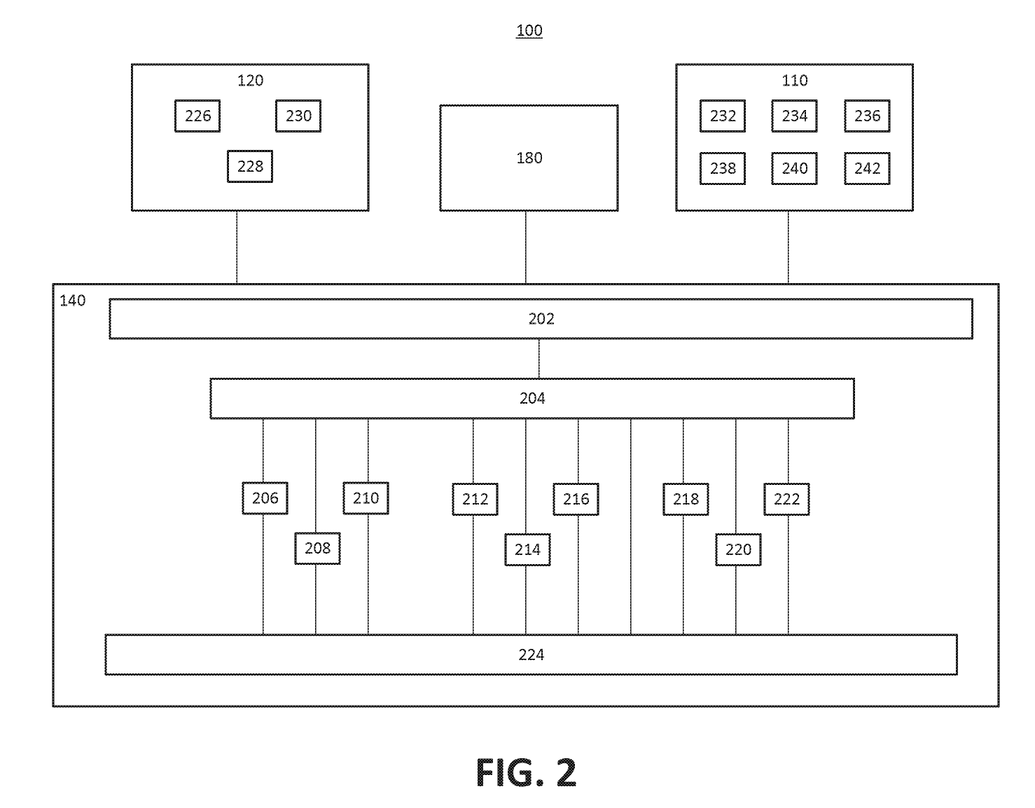

FIGS. 1 and 2 illustrate exemplary block diagrams of an environment 100 in which embodiments of the present disclosure may operate. In some embodiments, the environment 100 comprises a cloud-based project operations device 140. In some embodiments, the cloud-based project operations device 140 is electronically and/or communicatively coupled to a project foundation device 180, an external project implementation device 120, an external project application device 110, one or more databases 150, and/or the user device 170. The cloud-based project operations device 140 may be located remotely from the project foundation device 180, the external project implementation device 120, the external project application device 110, the one or more databases 150, and/or the user device 170. In this regard, for example, the cloud-based project operations device 140 may be located in a remote cloud server and electronically and/or communicatively coupled to the project foundation device 180, the external project implementation device 120, the external project application device 110, the one or more databases 150, and/or the user device 170 via at least the network 130. In some embodiments, the cloud-based project operations device 140 is configured via hardware, software, firmware, and/or a combination thereof, to perform data intake of one or more types of data.

Additionally, or alternatively, in some embodiments, the cloud-based project operations device 140 is configured via hardware, software, firmware, and/or a combination thereof, to generate and/or transmit command(s) that control, adjust, or otherwise impact operations of one or more of the project foundation device 180, the external project implementation device 120, the external project application device 110, the one or more databases 150, and/or the user device 170. Additionally, or alternatively, in some embodiments, the cloud-based project operations device 140 is configured via hardware, software, firmware, and/or a combination thereof, to perform data reporting, provide data, and/or other data output process(es) associated with monitoring or otherwise analyzing operations of one or more of the project foundation device 180, the external project implementation device 120, the external project application device 110, the one or more databases 150, and/or the user device 170. For example, in various embodiments, the cloud-based project operations device 140 may be configured to execute and/or perform one or more operations and/or functions described herein.

In some embodiments, the cloud-based project operations device 140 comprises a project operations security layer 202 configured to execute and/or perform one or more operations and/or functions described herein. For example, the project operations security layer 202 may be configured to control access permissions for the cloud-based project operations device 140. In some embodiments, the cloud-based project operations device 140 comprises a project orchestration predictive computing entity 204 configured to execute and/or perform one or more operations and/or functions described herein. In some embodiments, the cloud-based project operations device 140 comprises one or more internal predictive computing entities configured to execute and/or perform one or more operations and/or functions described herein. For example, the cloud-based project operations device 140 may comprise an inventory predictive computing entity 206, a program predictive computing entity 208, a project condition predictive computing entity 210, a project record predictive computing entity 212, a project component engineering predictive computing entity 214, a project command predictive computing entity 216, a project prompt predictive computing entity 218, a project operations predictive computing entity 220, a project services predictive computing entity 222, and/or the like. In some embodiments, the cloud-based project operations device 140 comprises an internal database 224 configured to execute and/or perform one or more operations and/or functions described herein. For example, the internal database 224 may be a vectorized database.

In some embodiments, the environment 100 comprises the external project implementation device 120. In some embodiments, the external project implementation device 120 is electronically and/or communicatively coupled to the project foundation device 180, the external project application device 110, the cloud-based project operations device 140, the one or more databases 150, and/or the user device 170. The external project implementation device 120 may be located remotely from the project foundation device 180, the external project application device 110, the cloud-based project operations device 140, the one or more databases 150, and/or the user device 170. In this regard, for example, the external project implementation device 120 may be located in a remote cloud server and electronically and/or communicatively coupled to the project foundation device 180, the external project application device 110, the cloud-based project operations device 140, the one or more databases 150, and/or the user device 170 via at least the network 130. In some embodiments, the external project implementation device 120 is configured via hardware, software, firmware, and/or a combination thereof, to perform data intake of one or more types of data.

Additionally, or alternatively, in some embodiments, the external project implementation device 120 is configured via hardware, software, firmware, and/or a combination thereof, to generate and/or transmit command(s) that control, adjust, or otherwise impact operations of one or more of the project foundation device 180, the external project application device 110, the cloud-based project operations device 140, the one or more databases 150, and/or the user device 170. Additionally, or alternatively, in some embodiments, the external project implementation device 120 is configured via hardware, software, firmware, and/or a combination thereof, to perform data reporting, provide data, and/or other data output process(es) associated with monitoring or otherwise analyzing operations of one or more of the project foundation device 180, the external project application device 110, the cloud-based project operations device 140, the one or more databases 150, and/or the user device 170. For example, in various embodiments, the external project implementation device 120 may be configured to execute and/or perform one or more operations and/or functions described herein.

In some embodiments, the external project implementation device 120 comprises one or more external predictive computing entities configured to execute and/or perform one or more operations and/or functions described herein. For example, the external project implementation device 120 may comprise a project extraction predictive computing entity 226, a project code predictive computing entity 228, a project bot predictive computing entity 230, and/or the like.

In some embodiments, the environment 100 comprises an external project application device 110. In some embodiments, the external project application device 110 is electronically and/or communicatively coupled to the project foundation device 180, the external project implementation device 120, the cloud-based project operations device 140, the one or more databases 150, and/or the user device 170. The external project application device 110 may be located remotely from the project foundation device 180, the external project implementation device 120, the cloud-based project operations device 140, the one or more databases 150, and/or the user device 170. In this regard, for example, the external project application device 110 may be located in a remote cloud server and electronically and/or communicatively coupled to the project foundation device 180, the external project implementation device 120, the cloud-based project operations device 140, the one or more databases 150, and/or the user device 170 via at least the network 130. In some embodiments, the external project application device 110 is configured via hardware, software, firmware, and/or a combination thereof, to perform data intake of one or more types of data.

Additionally, or alternatively, in some embodiments, the external project application device 110 is configured via hardware, software, firmware, and/or a combination thereof, to generate and/or transmit command(s) that control, adjust, or otherwise impact operations of one or more of the project foundation device 180, the external project implementation device 120, the cloud-based project operations device 140, the one or more databases 150, and/or the user device 170. Additionally, or alternatively, in some embodiments, the external project application device 110 is configured via hardware, software, firmware, and/or a combination thereof, to perform data reporting, provide data, and/or other data output process(es) associated with monitoring or otherwise analyzing operations of one or more of the project foundation device 180, the external project implementation device 120, the cloud-based project operations device 140, the one or more databases 150, and/or the user device 170. For example, in various embodiments, the external project application device 110 may be configured to execute and/or perform one or more operations and/or functions described herein.

In some embodiments, the external project application device 110 comprises one or more external computing applications configured to execute and/or perform one or more operations and/or functions described herein. For example, THE external project application device 110 may comprise a project operations computing application 232, a project impact value computing application 234, a project documentation computing application 236, a project component computing application 238, a project generation computing application 240, a project automation computing application 242, and/or the like.

In some embodiments, the environment 100 comprises the project foundation device 180. In some embodiments, the project foundation device 180 is electronically and/or communicatively coupled to the external project implementation device 120, the external project application device 110, the cloud-based project operations device 140, the one or more databases 150, and/or the user device 170. The project foundation device 180 may be located remotely from the external project implementation device 120, the external project application device 110, the cloud-based project operations device 140, the one or more databases 150, and/or the user device 170. In this regard, for example, the project foundation device 180 may be located in a remote cloud server and electronically and/or communicatively coupled to the external project implementation device 120, the external project application device 110, the cloud-based project operations device 140, the one or more databases 150, and/or the user device 170 via at least the network 130. In some embodiments, the project foundation device 180 is configured via hardware, software, firmware, and/or a combination thereof, to perform data intake of one or more types of data.

Additionally, or alternatively, in some embodiments, the project foundation device 180 is configured via hardware, software, firmware, and/or a combination thereof, to generate and/or transmit command(s) that control, adjust, or otherwise impact operations of one or more of the external project implementation device 120, the external project application device 110, the cloud-based project operations device 140, the one or more databases 150, and/or the user device 170. Additionally, or alternatively, in some embodiments, the project foundation device 180 is configured via hardware, software, firmware, and/or a combination thereof, to perform data reporting, provide data, and/or other data output process(es) associated with monitoring or otherwise analyzing operations of one or more of the external project implementation device 120, the external project application device 110, the cloud-based project operations device 140, the one or more databases 150, and/or the user device 170. For example, in various embodiments, the project foundation device 180 may be configured to execute and/or perform one or more operations and/or functions described herein.

The one or more databases 150 may be configured to receive, store, and/or transmit data. In some embodiments, the one or more databases 150 may be associated with data associated with the project foundation device 180, the external project implementation device 120, the external project application device 110, the cloud-based project operations device 140, and/or the user device 170. In some embodiments, the data may be received from the project foundation device 180, the external project implementation device 120, the external project application device 110, the cloud-based project operations device 140, and/or the user device 170. In some embodiments, the one or more databases 150 may be associated with data received from the project foundation device 180, the external project implementation device 120, the external project application device 110, the cloud-based project operations device 140, and/or the user device 170 in real-time. Additionally, or alternatively, the one or more databases 150 may be associated with data received from the project foundation device 180, the external project implementation device 120, the external project application device 110, the cloud-based project operations device 140, and/or the user device 170 on a periodic basis (e.g., the data may be received from the project foundation device 180, the external project implementation device 120, the external project application device 110, the cloud-based project operations device 140, the one or more databases 150, and/or the user device 170 once per day). Additionally, or alternatively, the one or more databases 150 may be associated with data received from the project foundation device 180, the external project implementation device 120, the external project application device 110, the cloud-based project operations device 140, and/or the user device 170 in response to a request for the data. Additionally, or alternatively, the one or more databases 150 may be associated with data inputted (e.g., by a user) into the project foundation device 180, the external project implementation device 120, the external project application device 110, the cloud-based project operations device 140, and/or the user device 170. Additionally, or alternatively, the one or more databases 150 may comprise an archived physical component database 402.

The user device 170 may be associated with users of the project foundation device 180, the external project implementation device 120, the external project application device 110, the cloud-based project operations device 140, and/or the one or more databases 150. In various embodiments, the project foundation device 180, the external project implementation device 120, the external project application device 110, the cloud-based project operations device 140, and/or the one or more databases 150 may generate and/or transmit a message, alert, or indication to a user via a user device 170. Additionally, or alternatively, a user device 170 may be utilized by a user to remotely access the project foundation device 180, the external project implementation device 120, the external project application device 110, the cloud-based project operations device 140, and/or the one or more databases 150. This may be by, for example, an application operating on the user device 170. A user may access the project foundation device 180, the external project implementation device 120, the external project application device 110, the cloud-based project operations device 140, and/or the one or more databases 150, remotely, including one or more visualizations, reports, and/or real-time displays.

In some embodiments, the project foundation device 180, the external project implementation device 120, the external project application device 110, the cloud-based project operations device 140, the one or more databases 150, and/or the user device 170 is associated with a determinable location. In some embodiments, the determinable location of the project foundation device 180, the external project implementation device 120, the external project application device 110, the cloud-based project operations device 140, the one or more databases 150, and/or the user device 170 represents an absolute position (e.g., GPS coordinates, latitude, and longitude locations, and/or the like) and/or a relative position (e.g., a point representation of the location of the project foundation device 180, the external project implementation device 120, the external project application device 110, the cloud-based project operations device 140, the one or more databases 150, and/or the user device 170 from a local origin point). In some embodiments, the project foundation device 180, the external project implementation device 120, the external project application device 110, the cloud-based project operations device 140, the one or more databases 150, and/or the user device 170 includes or otherwise is associated with a location sensor and/or software-driven location services that provide the location data representing the location corresponding to that the project foundation device 180, the external project implementation device 120, the external project application device 110, the cloud-based project operations device 140, the one or more databases 150, and/or the user device 170. In other embodiments the location of the project foundation device 180, the external project implementation device 120, the external project application device 110, the cloud-based project operations device 140, the one or more databases 150, and/or the user device 170 is stored and/or otherwise predetermined within a software environment, provided by a user and/or otherwise determinable to one or more systems.

Additionally, while FIGS. 1 and 2 illustrate certain components as separate, standalone entities communicating over the network 130, various embodiments are not limited to this configuration. In other embodiments, one or more components may be directly connected and/or share hardware or the like.

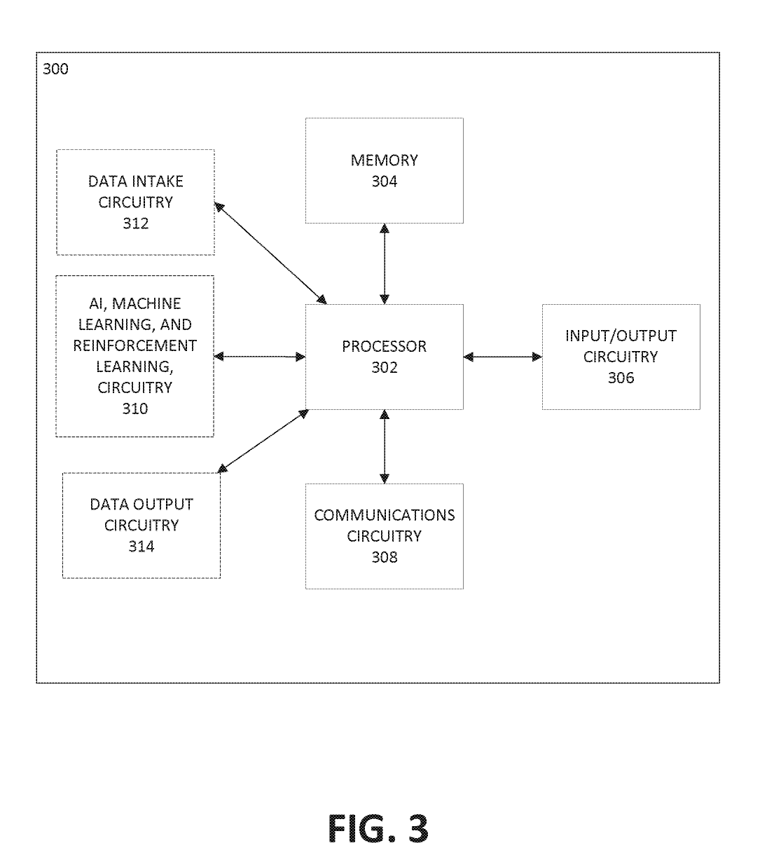

FIG. 3 illustrates an exemplary block diagram of an example apparatus that may be specially configured in accordance with an example embodiment of the present disclosure. Specifically, FIG. 3 depicts an example computing apparatus 300 (“apparatus 300”) specially configured in accordance with at least some example embodiments of the present disclosure. For example, the computing apparatus 300 may be embodied as one or more of a specifically configured personal computing apparatus, a specifically configured cloud-based computing apparatus, a specifically configured embedded computing device (e.g., configured for edge computing, and/or the like). Examples of an apparatus 300 may include, but is not limited to, the project foundation device 180, the external project implementation device 120, the external project application device 110, the cloud-based project operations device 140, the one or more databases 150, and/or the user device 170. The apparatus 300 includes processor 302, memory 304, input/output circuitry 306, communications circuitry 308, and/or optional artificial intelligence (“AI”) and machine learning circuitry 310. In some embodiments, the apparatus 300 is configured to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

In various embodiments, such as computing apparatus 300 of the project foundation device 180, the external project implementation device 120, the external project application device 110, the cloud-based project operations device 140, the one or more databases 150, and/or the user device 170 may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 300 embodies a particular, specially configured computing entity transformed to enable the specific operations described herein and provide the specific advantages associated therewith, as described herein.

Processor 302 or processor circuity 302 may be embodied in a number of different ways. In various embodiments, the use of the terms “processor” should be understood to include a single core processor, a multi-core processor, multiple processors internal to the apparatus 300, and/or one or more remote or “cloud” processor(s) external to the apparatus 300. In some example embodiments, processor 302 may include one or more processing devices configured to perform independently. Alternatively, or additionally, processor 302 may include one or more processor(s) configured in tandem via a bus to enable independent execution of operations, instructions, pipelining, and/or multithreading.

In an example embodiment, the processor 302 may be configured to execute instructions stored in the memory 304 or otherwise accessible to the processor. Alternatively, or additionally, the processor 302 may be configured to execute hard-coded functionality. As such, whether configured by hardware or software methods, or by a combination thereof, processor 302 may represent an entity (e.g., physically embodied in circuitry) capable of performing operations according to embodiments of the present disclosure while configured accordingly. Alternatively, or additionally, processor 302 may be embodied as an executor of software instructions, and the instructions may specifically configure the processor 302 to perform the various algorithms embodied in one or more operations described herein when such instructions are executed. In some embodiments, the processor 302 includes hardware, software, firmware, and/or a combination thereof that performs one or more operations described herein.

In some embodiments, the processor 302 (and/or co-processor or any other processing circuitry assisting or otherwise associated with the processor) is/are in communication with the memory 304 via a bus for passing information among components of the apparatus 300.

Memory 304 or memory circuitry 304 may be non-transitory and may include, for example, one or more volatile and/or non-volatile memories. In some embodiments, the memory 304 includes or embodies an electronic storage device (e.g., a computer readable storage medium). In some embodiments, the memory 304 is configured to store information, data, content, applications, instructions, or the like, for enabling an apparatus 300 to carry out various operations and/or functions in accordance with example embodiments of the present disclosure.

Input/output circuitry 306 may be included in the apparatus 300. In some embodiments, input/output circuitry 306 may provide output to the user and/or receive input from a user. The input/output circuitry 306 may be in communication with the processor 302 to provide such functionality. The input/output circuitry 306 may comprise one or more user interface(s). In some embodiments, a user interface may include a display that comprises the interface(s) rendered as a web user interface, an application user interface, a user device, a backend system, or the like. In some embodiments, the input/output circuitry 306 also includes a keyboard, a mouse, a joystick, a touch screen, touch areas, soft keys a microphone, a speaker, or other input/output mechanisms. The processor 302 and/or input/output circuitry 306 comprising the processor may be configured to control one or more operations and/or functions of one or more user interface elements through computer program instructions (e.g., software and/or firmware) stored on a memory accessible to the processor (e.g., memory 304, and/or the like). In some embodiments, the input/output circuitry 306 includes or utilizes a user-facing application to provide input/output functionality to a computing device and/or other display associated with a user.

Communications circuitry 308 may be included in the apparatus 300. The communications circuitry 308 may include any means such as a device or circuitry embodied in either hardware or a combination of hardware and software that is configured to receive and/or transmit data from/to a network and/or any other device, circuitry, or module in communication with the apparatus 300. In some embodiments the communications circuitry 308 includes, for example, a network interface for enabling communications with a wired or wireless communications network. Additionally, or alternatively, the communications circuitry 308 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 308 may include circuitry for interacting with an antenna(s) and/or other hardware or software to cause transmission of signals via the antenna(s) and/or to handle receipt of signals received via the antenna(s). In some embodiments, the communications circuitry 308 enables transmission to and/or receipt of data from a user device, one or more sensors, and/or other external computing device(s) in communication with the apparatus 300.

Data intake circuitry 312 may be included in the apparatus 300. The data intake circuitry 312 may include hardware, software, firmware, and/or a combination thereof, designed and/or configured to capture, receive, request, and/or otherwise gather data associated with operations of the project foundation device 180, the external project implementation device 120, the external project application device 110, the cloud-based project operations device 140, the one or more databases 150, and/or the user device 170. In some embodiments, the data intake circuitry 312 includes hardware, software, firmware, and/or a combination thereof, that communicates with one or more sensor(s) unit(s), and/or the like within the project foundation device 180, the external project implementation device 120, the external project application device 110, the cloud-based project operations device 140, the one or more databases 150, and/or the user device 170 to receive particular data. Additionally, or alternatively, in some embodiments, the data intake circuitry 312 includes hardware, software, firmware, and/or a combination thereof, that retrieves particular data associated with the project foundation device 180, the external project implementation device 120, the external project application device 110, the cloud-based project operations device 140, the one or more databases 150, and/or the user device 170 from one or more data repository/repositories accessible to the apparatus 300.

AI and machine learning circuitry 310 may be included in the apparatus 300. The AI and machine learning circuitry 310 may include hardware, software, firmware, and/or a combination thereof designed and/or configured to request, receive, process, generate, and transmit data, data structures, control signals, and electronic information for training and executing a trained AI and machine learning model configured for facilitating the operations and/or functionalities described herein. For example, in some embodiments the AI and machine learning circuitry 310 includes hardware, software, firmware, and/or a combination thereof, that identifies training data and/or utilizes such training data for training a particular machine learning model, AI, and/or other model to generate particular output data based at least in part on learnings from the training data. Additionally, or alternatively, in some embodiments, the AI and machine learning circuitry 310 includes hardware, software, firmware, and/or a combination thereof, that embodies or retrieves a trained machine learning model, AI and/or other specially configured model utilized to process inputted data. Additionally, or alternatively, in some embodiments, the AI and machine learning circuitry 310 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

Data output circuitry 314 may be included in the apparatus 300. The data output circuitry 314 may include hardware, software, firmware, and/or a combination thereof, that configures and/or generates an output based at least in part on data processed by the apparatus 300. In some embodiments, the data output circuitry 314 includes hardware, software, firmware, and/or a combination thereof, that generates a particular report based at least in part on the processed data, for example where the report is generated based at least in part on a particular reporting protocol. Additionally, or alternatively, in some embodiments, the data output circuitry 314 includes hardware, software, firmware, and/or a combination thereof, that configures a particular output data object, output data file, and/or user interface for storing, transmitting, and/or displaying. For example, in some embodiments, the data output circuitry 314 generates and/or specially configures a particular data output for transmission to another system sub-system for further processing. Additionally, or alternatively, in some embodiments, the data output circuitry 314 includes hardware, software, firmware, and/or a combination thereof, that causes rendering of a specially configured user interface based at least in part on data received by and/or processing by the apparatus 300.

In some embodiments, two or more of the sets of circuitries 302-314 are combinable. Alternatively, or additionally, one or more of the sets of circuitry 302-314 perform some or all of the operations and/or functionality described herein as being associated with another circuitry. In some embodiments, two or more of the sets of circuitry 302-314 are combined into a single module embodied in hardware, software, firmware, and/or a combination thereof. For example, in some embodiments, one or more of the sets of circuitry, for example the AI and machine learning circuitry 310, may be combined with the processor 302, such that the processor 302 performs one or more of the operations described herein with respect to the AI and machine learning circuitry 310.

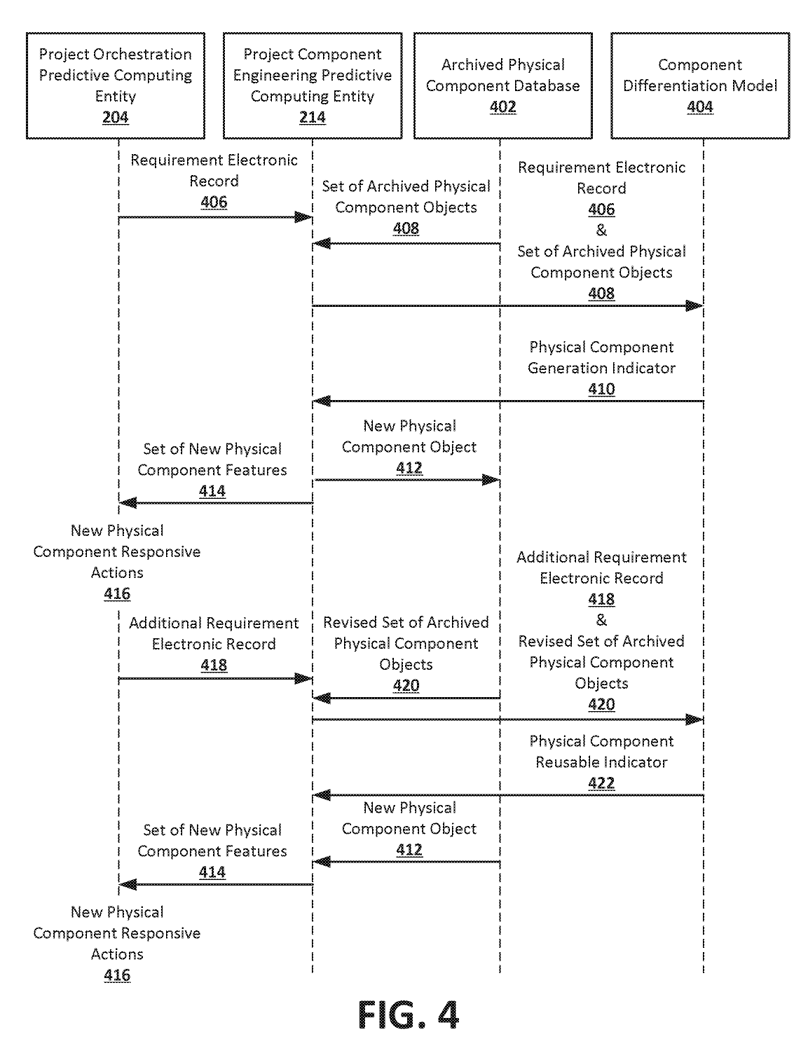

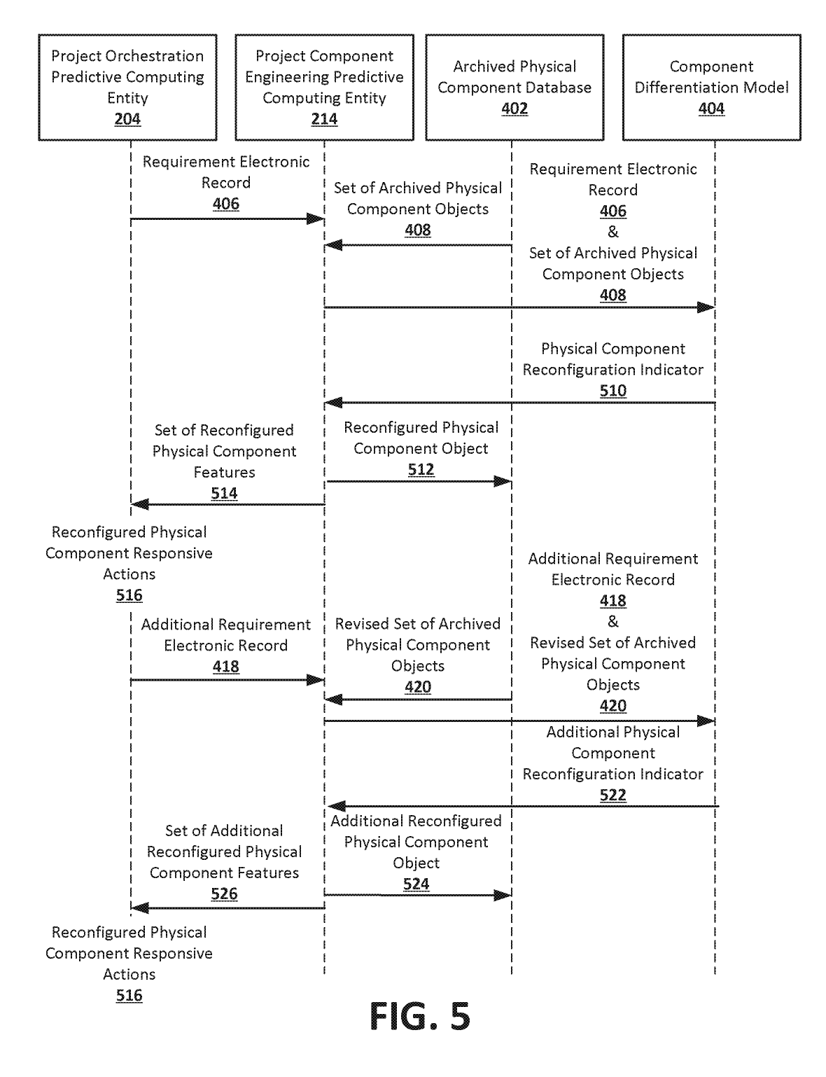

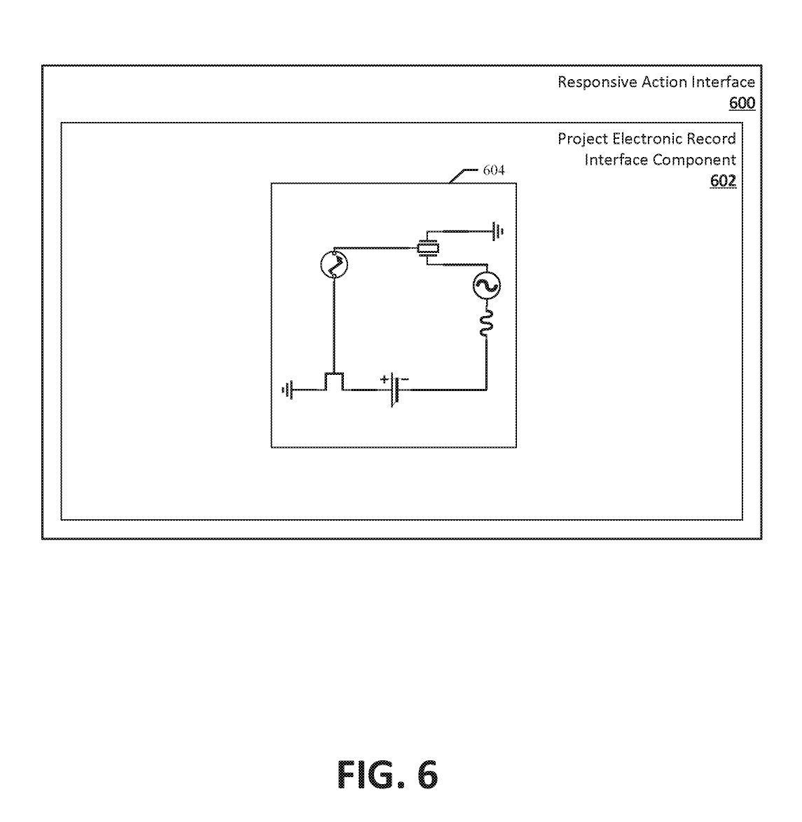

With reference to FIGS. 1-6, in some embodiments, a project may be a collection of components that may be implemented in a configured manner to accomplish one or more tasks. In this regard, for example, a project may be a collection of components that may be implemented in a configured manner in order to control the temperature of a building. For example, a project may be a collection of configured components that include temperature sensors, temperature control systems, circuits, and/or heating, ventilation, and air conditioning (HVAC) units that may be implemented in order to control the temperature of a building. In this regard, in some embodiments, a physical component may be any component configured to, in combination with other components, construct a configured component such as a temperature sensor, circuit, or HVAC unit.

In some embodiments, the cloud-based project operations device 140 is configured to access a requirement electronic record 406. For example, the cloud-based project operations device 140 may be configured to access a requirement electronic record 406 at the project orchestration predictive computing entity 204 (e.g., the cloud-based project operations device 140 is configured to access a requirement electronic record 406 using the project orchestration predictive computing entity 204).

In some embodiments, a requirement electronic record 406 comprises an electronic record that is representative of one or more physical component features. In this regard, in some embodiments, a requirement electronic record 406 may be one or more of a text document, a schematic drawing, a 3D model, a virtual 3D model, a computer-aided design (CAD) file, an image, a video, and/or the like. For example, a requirement electronic record 406 may be a schematic drawing that depicts one or more physical component features. As another example, a requirement electronic record 406 may be a video that depicts one or more physical component features. As another example, a requirement electronic record 406 may be a text document that describes one or more physical component features. As another example, a requirement electronic record 406 may be a 3D model that depicts one or more physical component features. As another example, a requirement electronic record 406 may be a computer-aided design (CAD) file that describes and/or depicts one or more physical component features. As another example, a requirement electronic record 406 may be an image that depicts one or more physical component features.

In some embodiments, a physical component feature comprises one or more items of data representative of a requirement, a criteria, and/or a constraint associated with a physical component to be used in a proposed project that must be satisfied in order to implement a proposed project. For example, a physical component feature may be one or more items of data that are representative of a requirement, a criteria, and/or a constraint associated with a physical component to be used in a proposed project that must be satisfied in order to implement a proposed project that includes controlling the temperature of a building. In this regard, for example, a physical component feature may be representative of a maximum surface area (e.g., a constraint, a criteria, and/or a requirement) of a circuit board (e.g., a physical component) to be used in a proposed project that must be satisfied in order for the proposed project to be implemented. As another example, a physical component feature may be representative of a particular range of acceptable volumes (e.g., a constraint, a criteria, and/or a requirement) of an HVAC unit (e.g., a physical component) to be used in a proposed project that must be satisfied in order for the proposed project to be implemented.

In some embodiments, accessing a requirement electronic record 406 comprises the cloud-based project operations device 140 being configured to retrieve a requirement electronic record 406. For example, the cloud-based project operations device 140 may be configured to retrieve a requirement electronic record 406 from the one or more databases 150 using the project orchestration predictive computing entity 204. As another example, cloud-based project operations device 140 may be configured to retrieve a requirement electronic record 406 from the internal databases 224 using the project orchestration predictive computing entity 204. In some embodiments, accessing a requirement electronic record 406 comprises the cloud-based project operations device 140 being configured to receive a requirement electronic record 406. For example, the cloud-based project operations device 140 may be configured to receive a requirement electronic record 406 from the project foundation device 180. In some embodiments, prior to the cloud-based project operations device 140 accessing a requirement electronic record 406 at the project orchestration predictive computing entity 204, a requirement electronic record 406 may be processed by the project operations security layer 202 using one or more cybersecurity operations. In some embodiments, accessing a requirement electronic record 406 comprises the cloud-based project operations device 140 providing access to a requirement electronic record 406 to project component engineering predictive computing entity 214 via project orchestration predictive computing entity 204.

In some embodiments, the cloud-based project operations device 140 is configured to retrieve a set of archived physical component objects 408 from the archived physical component database 402. For example, the cloud-based project operations device 140 may be configured to retrieve a set of archived physical component objects 408 from the archived physical component database 402 using the project component engineering predictive computing entity 214. In some embodiments, archived physical component database 402 is configured to store the set of archived physical component objects 408.

In some embodiments, an archived physical component object comprises one or more items of data that describes a physical component that was implemented in a completed, previous, and/or archived project. In this regard, in some embodiments, the set of archived physical component objects 408 is representative of a collection of archived physical component objects that are associated with physical components that were constructed and/or implemented in a completed, previous, and/or archived project. For example, an archived physical component object may be representative of a temperature sensor, a circuit, an HVAC unit or any discrete, individual component used to construct a temperature sensor, a circuit, or an HVAC unit. Said differently, for example, an archived physical component object may be representative of an archived physical component that formed a portion of a completed, previous, and/or archived project.

In some embodiments, the cloud-based project operations device 140 is configured to generate a physical component requirement indication. For example, the cloud-based project operations device 140 may be configured to generate a physical component requirement indication using the project component engineering predictive computing entity 214. In some embodiments, the cloud-based project operations device 140 is configured to generate a physical component requirement indication based on a requirement electronic record 406 and/or at least one of a set of archived physical component objects 408. In some embodiments, a physical component requirement indication comprises a physical component generation indicator 410. Additionally, or alternatively, a physical component requirement indication comprises a physical component reconfiguration indicator 510. Said differently, for example, a physical component requirement indication may be a physical component generation indicator 410 or a physical component reconfiguration indicator 510.

In some embodiments, a physical component generation indicator 410 comprises one or more items of data that indicates that the set of archived physical component objects 408 does not include an archived physical component object that may be used to satisfy a physical component feature associated with a requirement electronic record 406. In this regard, for example, a physical component generation indicator 410 may indicate that the set of archived physical component objects 408 does not include an archived physical component object that satisfies a requirement, a criteria, and/or a constraint associated with a physical component to be used in a proposed project that must be satisfied in order to implement a proposed project. For example, a physical component generation indicator 410 may indicate that the set of archived physical component objects 408 does not include an archived physical component object representative of an HVAC unit having a volume that is within a particular range of acceptable volumes. Said differently, for example, a physical component generation indicator 410 may indicate that the set of archived physical component objects 408 does not include an archived physical component that describes a completed, previous, and/or archived physical component that may be used to satisfy a physical component feature associated with a requirement electronic record 406.

In some embodiments, the cloud-based project operations device 140 is configured to generate a physical component generation indicator 410 based on a requirement electronic record 406 and/or at least one of a set of archived physical component objects 408 (e.g., using the project component engineering predictive computing entity 214). For example, the cloud-based project operations device 140 may be configured to generate a physical component generation indicator 410 by applying a requirement electronic record 406 and/or at least one of a set of archived physical component objects 408 to a component differentiation model 404. In this regard, in some embodiments, the component differentiation model 404 may be configured to generate a physical component generation indicator 410 by comparing a requirement electronic record 406 and at least one of a set of archived physical component objects 408.

In some embodiments, the cloud-based project operations device 140 is configured to generate a new physical component object 412. For example, the cloud-based project operations device 140 may be configured to generate a new physical component object 412 using the project component engineering predictive computing entity 214. In some embodiments, the cloud-based project operations device 140 is configured to generate a new physical component object 412 in response to generating a physical component generation indicator 410. In this regard, in some embodiments, the cloud-based project operations device 140 is configured to generate a new physical component object 412 based on a physical component generation indicator 410.

In some embodiments, a new physical component object 412 comprises one or more items of data that describes a physical component that may be implemented in a proposed project associated with a requirement electronic record 406 and does not correspond to a physical component associated with at least one of the set of archived physical component objects (e.g., a new physical component object 412 is associated with a new physical component). In this regard, in some embodiments, a new physical component object may describe a physical component that satisfies a physical component feature associated with a requirement electronic record 406. For example, a new physical component object 412 may describe an HVAC unit having a volume that is within a particular range of acceptable volumes. In some embodiments, the new physical component object 412 comprises a 3-dimensional virtual model that depicts a physical component that may be implemented in a proposed project associated with a requirement electronic record 406.

In some embodiments, the cloud-based project operations device 140 is configured to extract a set of new physical component features 414 from a new physical component object 412. For example, the cloud-based project operations device 140 is configured to extract a set of new physical component features from a new physical component object 412 using the project component engineering predictive computing entity 214. In some embodiments, a new physical component feature comprises one or more items of data representative of one or more subsidiary components of a physical component represented by a new physical component object 412. For example, the set of new physical component features 414 may be representative of screws, circuity, enclosures, condensers, fans, and/or the like of an HVAC unit. Said differently, for example, the set of new physical component features 414 may be representative of the materials and/or components that make of a physical component represented by a new physical component object 412 (e.g., a bill of materials). In this regard, in some embodiments, the new physical component object 412 comprises a 3-dimensional virtual model that depicts a set of new physical component features 414 of a physical component that may be implemented in a proposed project associated with a requirement electronic record 406.

In some embodiments, the cloud-based project operations device 140 is configured to cause performance of one or more new physical component responsive actions 416. For example, the cloud-based project operations device 140 is configured to cause performance of one or more new physical component responsive actions 416 using the project orchestration predictive computing entity 204. In some embodiments, the cloud-based project operations device 140 is configured to cause performance of one or more new physical component responsive actions 416 based on the new physical component object 412. In some embodiments, the cloud-based project operations device 140 is configured to cause performance of one or more new physical component responsive actions 416 based on the set of new physical component features 414 associated with the new physical component object 412. In this regard, in some embodiments, causing performance of one or more new physical component responsive actions comprises the cloud-based project operations device 140 being configured to generate one or more project electronic records. For example, the cloud-based project operations device 140 may be configured to generate one or more project electronic records using the project orchestration predictive computing entity 204 and/or the project record predictive computing entity 212. In this regard, in some embodiments, a project electronic record may comprise a plan, design, and/or process for implementing the proposed project corresponding to a requirement electronic record 406 using the new physical component object 412. For example, a project electronic record may comprise a plan, design, and/or process for implementing the proposed project corresponding to a requirement electronic record 406 that describes how to configure a set of new physical component features 414 in order to implement a physical component associated with the new physical component object 412 in the proposed project.

In some embodiments, causing performance of one or more new physical component responsive actions 416 comprises the project component engineering predictive computing entity 214 being configured to generate a project electronic record interface component 602. In some embodiments, the project electronic record interface component 602 is configured to display a visual representation 604 of one or more project electronic records. For example, the visual representation 604 may be a representation of a project electronic record that comprises a plan, design, and/or process for implementing the proposed project corresponding to a requirement electronic record 406 using the new physical component object 412. In some embodiments, causing performance of one or more new physical component responsive actions 416 comprises the cloud-based project operations device 140 being configured to cause a project electronic record interface component 602 to be rendered to responsive action interface 600. In some embodiments, the responsive action interface 600 may be provided on a display associated with the cloud-based project operations device 140 and/or a display associated with the project foundation device 180.

In some embodiments, causing performance of one or more new physical component responsive actions 416 comprises the cloud-based project operations device 140 being configured to cause a component inventory record to be updated. In some embodiments, a component inventory record is a record that indicates one or more new physical components that may be included in a project associated with a project electronic record (e.g., a project electronic record comprising the new physical component object 412). In this regard, for example, a component inventory record may be updated to be associated with an indication that a new physical component is necessary for the manufacturing of a project component associated with a project electronic record. As another example, a component inventory record may be updated to cause, by cloud-based project operations device 140 via inventory predictive computing entity 206, procurement of a new physical component. In this regard, in some embodiments, causing performance of one or more new physical component responsive actions 416 may comprise causing one or more manufacturing systems to operate in order to generate a new physical component (e.g., a new physical component associated with the new physical component object 412). Additionally, or alternatively, causing performance of one or more new physical component responsive actions 416 may comprise causing one or more systems to shut down (e.g., after the new physical component has been generated).

In some embodiments, causing performance of one or more new physical component responsive actions 416 comprises the cloud-based project operations device 140 being configured to transmit a project electronic record to the project foundation device 180. For example, when a project electronic record is generated, the cloud-based project operations device 140 may be configured to transmit the project electronic record to the project foundation device 180 indicating that project electronic record (e.g., a project electronic record comprising the new physical component object 412) has been generated based on a requirement electronic record 406 by the cloud-based project operations device 140.

In some embodiments, a physical component reconfiguration indicator 510 comprises one or more items of data that indicates that the set of archived physical component objects 408 includes an archived physical component object representative of a physical component that may be reconfigured such that it may be used to satisfy a physical component feature associated with a requirement electronic record 406. In this regard, for example, a physical component reconfiguration indicator 510 may indicate that the set of archived physical component objects 408 includes an archived physical component object representative of a physical component that may be reconfigured to satisfy a requirement, a criteria, and/or a constraint associated with a physical component to be used in a proposed project that must be satisfied in order to implement a proposed project. For example, a physical component reconfiguration indicator 510 may indicate that the set of archived physical component objects 408 includes an archived physical component object representative of a circuit board having a surface area that may be reconfigured (e.g., made smaller). Said differently, for example, a physical component reconfiguration indicator 510 may indicate that the set of archived physical component objects 408 includes an archived physical component that describes a completed, previous, and/or archived physical component that may be reconfigured such that it that may be used to satisfy a physical component feature associated with a requirement electronic record 406.

In some embodiments, the cloud-based project operations device 140 is configured to generate a physical component reconfiguration indicator 510 based on a requirement electronic record 406 and/or at least one of a set of archived physical component objects 408 (e.g., using the project component engineering predictive computing entity 214). For example, the cloud-based project operations device 140 may be configured to generate a physical component reconfiguration indicator 510 by applying a requirement electronic record 406 and/or at least one of a set of archived physical component objects 408 to a component differentiation model 404. In this regard, in some embodiments, the component differentiation model 404 may be configured to generate a physical component reconfiguration indicator 510 by comparing a requirement electronic record 406 and at least one of a set of archived physical component objects 408.

In some embodiments, the cloud-based project operations device 140 is configured to generate a reconfigured physical component object 512. For example, the cloud-based project operations device 140 may be configured to generate a reconfigured physical component object 512 using the project component engineering predictive computing entity 214. In some embodiments, the cloud-based project operations device 140 is configured to generate a reconfigured physical component object 512 in response to generating a physical component reconfiguration indicator 510. In this regard, in some embodiments, the cloud-based project operations device 140 is configured to generate a reconfigured physical component object 512 based on a physical component reconfiguration indicator 510.

In some embodiments, a reconfigured physical component object 512 comprises one or more items of data that describes a physical component that may be implemented in a proposed project associated with a requirement electronic record 406 and corresponds to a physical component associated with at least one of the set of archived physical component objects (e.g., a reconfigured physical component object 512 is associated with a reconfigured version of a physical component associated with at least one of the set of archived physical component objects). In this regard, in some embodiments, a reconfigured physical component object 512 may describe a physical component that satisfies a physical component feature associated with a requirement electronic record 406. For example, a reconfigured physical component object 512 may describe an HVAC unit that has been reconfigured to have a volume that is within a particular range of acceptable volumes. In some embodiments, the reconfigured physical component object 512 comprises a 3-dimensional virtual model that depicts a physical component that may be implemented in a proposed project associated with a requirement electronic record 406.

In some embodiments, the cloud-based project operations device 140 is configured to extract a set of reconfigured physical component features 514 from a reconfigured physical component object 512. For example, the cloud-based project operations device 140 is configured to extract a set of reconfigured physical component features 514 from a reconfigured physical component object 512 using the project component engineering predictive computing entity 214. In some embodiments, a reconfigured physical component feature comprises one or more items of data representative of one or more subsidiary components of a physical component represented by a reconfigured physical component object 512. For example, the set of reconfigured physical component features 514 may be representative of screws, circuity, enclosures, condensers, fans, and/or the like of an HVAC unit that has been reconfigured in order to be implemented in a proposed project. Said differently, for example, the set of reconfigured physical component features 514 may be representative of the materials and/or components that make of a physical component represented by a reconfigured physical component object 512 (e.g., a bill of materials). In this regard, in some embodiments, the reconfigured physical component object 512 comprises a 3-dimensional virtual model that depicts a set of reconfigured physical component features 514 of a physical component that may be implemented in a proposed project associated with a requirement electronic record 406.

In some embodiments, the cloud-based project operations device 140 is configured to cause performance of one or more reconfigured physical component responsive actions 516. For example, the cloud-based project operations device 140 is configured to cause performance of one or more reconfigured physical component responsive actions 516 using the project orchestration predictive computing entity 204. In some embodiments, the cloud-based project operations device 140 is configured to cause performance of one or more reconfigured physical component responsive actions 516 based on the reconfigured physical component object 512. In some embodiments, the cloud-based project operations device 140 is configured to cause performance of one or more reconfigured physical component responsive actions 516 based on the set of reconfigured physical component features 514 associated with the reconfigured physical component object 512. In this regard, in some embodiments, causing performance of one or more reconfigured physical component responsive actions 516 comprises the cloud-based project operations device 140 being configured to generate one or more project electronic records. For example, the cloud-based project operations device 140 may be configured to generate one or more project electronic records using the project orchestration predictive computing entity 204 and/or the project record predictive computing entity 212. In this regard, in some embodiments, a project electronic record may comprise a plan, design, and/or process for implementing the proposed project corresponding to a requirement electronic record 406 using the reconfigured physical component object 512. For example, a project electronic record may comprise a plan, design, and/or process for implementing the proposed project corresponding to a requirement electronic record 406 that describes how to configure a set of reconfigured physical component features 514 in order to implement a physical component associated with the reconfigured physical component object 512 in the proposed project.

In some embodiments, causing performance of one or more reconfigured physical component responsive actions 516 comprises the project component engineering predictive computing entity 214 being configured to generate a project electronic record interface component 602. In some embodiments, the project electronic record interface component 602 is configured to display a visual representation 604 of one or more project electronic records. For example, the visual representation 604 may be a representation of a project electronic record that comprises a plan, design, and/or process for implementing the proposed project corresponding to a requirement electronic record 406 using the reconfigured physical component object 512. In some embodiments, causing performance of one or more reconfigured physical component responsive actions 516 comprises the cloud-based project operations device 140 being configured to cause a project electronic record interface component 602 to be rendered to responsive action interface 600. In some embodiments, the responsive action interface 600 may be provided on a display associated with the cloud-based project operations device 140 and/or a display associated with the project foundation device 180.

In some embodiments, causing performance of one or more reconfigured physical component responsive actions 516 comprises the cloud-based project operations device 140 being configured to cause a component inventory record to be updated. In some embodiments, a component inventory record is a record that indicates one or more reconfigured physical components that may be included in a project associated with a project electronic record (e.g., a project electronic record comprising the reconfigured physical component object 512). In this regard, for example, a component inventory record may be updated to be associated with an indication that a reconfigured physical component is necessary for the manufacturing of a project component associated with a project electronic record. As another example, a component inventory record may be updated to cause, by cloud-based project operations device 140 via inventory predictive computing entity 206, procurement of a reconfigured physical component. In this regard, in some embodiments, causing performance of one or more reconfigured physical component responsive actions 516 may comprise causing one or more manufacturing systems to operate in order to generate a reconfigured physical component (e.g., a reconfigured physical component associated with the reconfigured physical component object 512). Additionally, or alternatively, causing performance of one or more reconfigured physical component responsive actions 516 may comprise causing one or more systems to shut down (e.g., after the reconfigured physical component has been generated).

In some embodiments, causing performance of one or more reconfigured physical component responsive actions 516 comprises the cloud-based project operations device 140 being configured to transmit a project electronic record to the project foundation device 180. For example, when a project electronic record is generated, the cloud-based project operations device 140 may be configured to transmit the project electronic record to the project foundation device 180 indicating that project electronic record (e.g., a project electronic record comprising the reconfigured physical component object 512) has been generated based on a requirement electronic record 406 by the cloud-based project operations device 140.

In some embodiments, the cloud-based project operations device 140 is configured to store the new physical component object 412 in the archived physical component database 402. For example, the cloud-based project operations device 140 may be configured to store the new physical component object 412 in the archived physical component database 402 using the project orchestration predictive computing entity 204 and/or the project component engineering predictive computing entity 214. In some embodiments, by storing the new physical component object 412 in the archived physical component database 402 the cloud-based project operations device 140 is configured to generate a revised set of archived physical component objects 420. In some embodiments, the revised set of archived physical component objects 420 comprises the new physical component object 412 and/or the set of archived physical component objects 408. In this regard, for example, the new physical component object 412 may be used for responding to other requirement electronic records.

In some embodiments, the cloud-based project operations device 140 is configured to access an additional requirement electronic record 418. For example, the cloud-based project operations device 140 may be configured to access the additional requirement electronic record 418 at the project orchestration predictive computing entity 204 (e.g., the cloud-based project operations device 140 is configured to access the additional requirement electronic record 418 using the project orchestration predictive computing entity 204). In some embodiments, an additional requirement electronic record 418 comprises an additional physical component feature. In some embodiments, an additional physical component feature comprises one or more items of data representative of a requirement, a criteria, and/or a constraint associated with a physical component to be used in an additional proposed project that must be satisfied in order to implement an additional proposed project. Said differently, for example, additional requirement electronic record 418 may have a similar structure and/or form as a requirement electronic record 406 but corresponds to a different proposed project than the requirement electronic record 406. In this regard, for example, the cloud-based project operations device 140 may be configured to access the additional requirement electronic record 418 after the cloud-based project operations device 140 has caused performance of one or more new physical component responsive actions 416 and/or one or more reconfigured physical component responsive actions 516.

In some embodiments, the cloud-based project operations device 140 is configured to retrieve the revised set of archived physical component objects 420 from the archived physical component database 402. For example, the cloud-based project operations device 140 may be configured to retrieve the revised set of archived physical component objects 420 from the archived physical component database 402 using the project component engineering predictive computing entity 214.

In some embodiments, the cloud-based project operations device 140 is configured to generate an additional physical component requirement indication. For example, the cloud-based project operations device 140 may be configured to generate an additional physical component requirement indication using the project component engineering predictive computing entity 214. In some embodiments, the cloud-based project operations device 140 is configured to generate an additional physical component requirement indication based on an additional requirement electronic record 418 and/or at least one of the revised set of archived physical component objects 420.

In some embodiments, an additional physical component requirement indication comprises an additional physical component generation indicator. In some embodiments, an additional physical component generation indicator comprises one or more items of data that indicates that the revised set of archived physical component objects 420 does not include an archived physical component object that may be used to satisfy an additional physical component feature associated with the additional requirement electronic record 418 and that the new physical component object 412 cannot be used to satisfy an additional physical component feature associated with the additional requirement electronic record 418. Said differently, for example, an additional physical component generation indicator may be similar to a physical component generation indicator but correspond to the additional requirement electronic record 418 rather than the requirement electronic record 406.

In some embodiments, an additional physical component requirement indication comprises an additional physical component reconfiguration indicator 522. In some embodiments, an additional physical component reconfiguration indicator 522 comprises one or more items of data that indicates that the revised set of archived physical component objects 420 includes an archived physical component object representative of a physical component that may be reconfigured such that it may be used to satisfy an additional physical component feature associated with the additional requirement electronic record 418 and/or that the new physical component object 412 may be reconfigured to be used to satisfy an additional physical component feature associated with the additional requirement electronic record 418. Said differently, for example, an additional physical component reconfiguration indicator 522 may be similar to a physical component reconfiguration indicator 510 but correspond to the additional requirement electronic record 418 rather than the requirement electronic record 406.

In some embodiments, an additional physical component requirement indication comprises a physical component reusable indicator 422. In some embodiments, a physical component reusable indicator 422 comprises one or more items of data that indicates that the new physical component object 412 in the revised set of archived physical component objects 420 may be used to satisfy an additional physical component feature associated with the additional requirement electronic record 418. Said differently, for example, an additional physical component requirement indication may be an additional physical component generation indicator, an additional physical component reconfiguration indicator 522, and/or a physical component reusable indicator 422.

In some embodiments, the cloud-based project operations device 140 is configured to generate an additional physical component requirement indication based on the additional requirement electronic record 418 and/or at least one of the revised set of archived physical component objects 420 (e.g., using the project component engineering predictive computing entity 214). For example, the cloud-based project operations device 140 may be configured to generate an additional physical component requirement indication by applying the additional requirement electronic record 418 and/or at least one of the revised set of archived physical component objects 420 to a component differentiation model 404. In this regard, in some embodiments, the component differentiation model 404 may be configured to generate an additional physical component requirement indication by comparing the additional requirement electronic record 418 and at least one archived physical component object of the revised set of archived physical component objects 420.

In some embodiments, the component differentiation model 404 may comprise hardware and/or software that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate physical component requirement indications and/or additional physical component requirement indications. In this regard, in some embodiments, the component differentiation model 404 may be configured to utilize one or more of any type of machine learning, rules-based, and/or artificial intelligence techniques including one or more of clustering techniques (e.g., k-means techniques, expectation maximization techniques, centroid neural network techniques), computer vision techniques, supervised learning (e.g., using user feedback), unsupervised learning, semi-supervised learning, reinforcement learning, sequence modeling techniques, language processing techniques, neural network techniques, and/or generative artificial intelligence techniques.

In some embodiments, the cloud-based project operations device 140 is configured to generate an additional project electronic record that comprises the new physical component object 412 based on the physical component reusable indicator 422. In this regard, in some embodiments, an additional project electronic record may comprise a plan, design, and/or process for implementing an additional proposed project corresponding to the additional requirement electronic record 418 using the new physical component object 412 that was previously used in a proposed project corresponding to the requirement electronic record 406.

In some embodiments, the cloud-based project operations device 140 is configured to generate an additional project electronic record that comprises the additional reconfigured physical component object 524 based on the additional physical component reconfiguration indicator 522. In this regard, in some embodiments, an additional project electronic record may comprise a plan, design, and/or process for implementing an additional proposed project corresponding to the additional requirement electronic record 418 using the additional reconfigured physical component object 524. In some embodiments, the additional reconfigured physical component object 524 comprises a set of additional reconfigured physical component features 526. In some embodiments, an additional reconfigured physical component feature of set of additional reconfigured physical component features 526 comprises one or more items of data representative of one or more subsidiary components of a physical component represented by the additional reconfigured physical component object 524.

### Example Methods

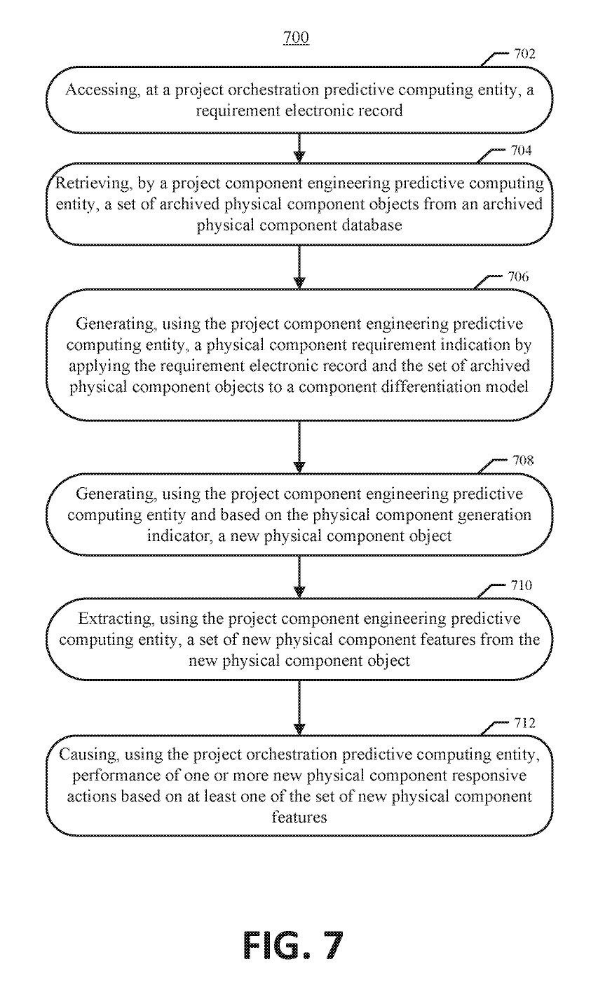

Referring now to FIG. 7, a flowchart providing an example method 700 is illustrated. In this regard, FIG. 7 illustrates operations that may be performed by the project foundation device 180, the external project implementation device 120, the external project application device 110, the cloud-based project operations device 140, the one or more databases 150, and/or the user device 170. In some embodiments, the method 700 comprises operations for generating a new physical component object. In some embodiments, the example method 700 defines a computer-implemented process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 700.

As shown in block 702, the method 700 may comprise accessing, at a project orchestration predictive computing entity, a requirement electronic record. In some embodiments, the requirement electronic record is representative of a physical component feature. As described above, in some embodiments, a physical component feature comprises one or more items of data representative of a requirement, a criteria, and/or a constraint associated with a physical component to be used in a proposed project that must be satisfied in order to implement a proposed project. For example, a physical component feature may be one or more items of data that are representative of a requirement, a criteria, and/or a constraint associated with a physical component to be used in a proposed project that must be satisfied in order to implement a proposed project that includes controlling the temperature of a building. In this regard, for example, a physical component feature may be representative of a maximum surface area (e.g., a constraint, a criteria, and/or a requirement) of a circuit board (e.g., a physical component) to be used in a proposed project that must be satisfied in order for the proposed project to be implemented. As another example, a physical component feature may be representative of a particular range of acceptable volumes (e.g., a constraint, a criteria, and/or a requirement) of an HVAC unit (e.g., a physical component) to be used in a proposed project that must be satisfied in order for the proposed project to be implemented.

As shown in block 704, the method 700 may comprise retrieving, by a project component engineering predictive computing entity, a set of archived physical component objects from an archived physical component database. As described above, in some embodiments, the cloud-based project operations device 140 is configured to retrieve a set of archived physical component objects 408 from the archived physical component database 402. For example, the cloud-based project operations device 140 may be configured to retrieve a set of archived physical component objects 408 from the archived physical component database 402 using the project component engineering predictive computing entity 214. In some embodiments, archived physical component database 402 is configured to store the set of archived physical component objects 408. In some embodiments, an archived physical component object comprises one or more items of data that describes a physical component that was implemented in a completed, previous, and/or archived project. In this regard, in some embodiments, the set of archived physical component objects 408 is representative of a collection of archived physical component objects that are associated with physical components that were constructed and/or implemented in a completed, previous, and/or archived project. For example, an archived physical component object may be representative of a temperature sensor, a circuit, an HVAC unit or any discrete, individual component used to construct a temperature sensor, a circuit, or an HVAC unit. Said differently, for example, an archived physical component object may be representative of an archived physical component that formed a portion of a completed, previous, and/or archived project.

As shown in block 706, the method 700 may comprise generating, using the project component engineering predictive computing entity, a physical component requirement indication by applying the requirement electronic record 406 and the set of archived physical component objects 408 to a component differentiation model. In some embodiments, the physical component requirement indication comprises a physical component generation indicator or a physical component reconfiguration indicator.

As described above, in some embodiments, the cloud-based project operations device 140 is configured to generate a physical component requirement indication. For example, the cloud-based project operations device 140 may be configured to generate a physical component requirement indication using the project component engineering predictive computing entity 214. In some embodiments, the cloud-based project operations device 140 is configured to generate a physical component requirement indication based on a requirement electronic record 406 and/or at least one of a set of archived physical component objects 408. In some embodiments, a physical component requirement indication comprises a physical component generation indicator 410. Additionally, or alternatively, a physical component requirement indication comprises a physical component reconfiguration indicator. Said differently, for example, a physical component requirement indication may be a physical component generation indicator or a physical component reconfiguration indicator. In some embodiments, a physical component generation indicator 410 comprises one or more items of data that indicates that the set of archived physical component objects 408 does not include an archived physical component object that may be used to satisfy a physical component feature associated with a requirement electronic record 406. In this regard, for example, a physical component generation indicator 410 may indicate that the set of archived physical component objects 408 does not include an archived physical component object that satisfies a requirement, a criteria, and/or a constraint associated with a physical component to be used in a proposed project that must be satisfied in order to implement a proposed project. For example, a physical component generation indicator 410 may indicate that the set of archived physical component objects 408 does not include an archived physical component object representative of an HVAC unit having a volume that is within a particular range of acceptable volumes. Said differently, for example, a physical component generation indicator 410 may indicate that the set of archived physical component objects 408 does not include an archived physical component that describes a completed, previous, and/or archived physical component that may be used to satisfy a physical component feature associated with a requirement electronic record 406.

In some embodiments, the cloud-based project operations device 140 is configured to generate a physical component generation indicator 410 based on a requirement electronic record 406 and/or at least one of a set of archived physical component objects 408 (e.g., using the project component engineering predictive computing entity 214). For example, the cloud-based project operations device 140 may be configured to generate a physical component generation indicator 410 by applying a requirement electronic record 406 and/or at least one of a set of archived physical component objects 408 to a component differentiation model 404. In this regard, in some embodiments, the component differentiation model 404 may be configured to generate a physical component generation indicator 410 by comparing a requirement electronic record 406 and at least one of a set of archived physical component objects 408.

As shown in block 708, the method 700 may comprise generating, using the project component engineering predictive computing entity and based on the physical component generation indicator, a new physical component object. As described above, in some embodiments, the cloud-based project operations device 140 is configured to generate a new physical component object 412. For example, the cloud-based project operations device 140 may be configured to generate a new physical component object 412 using the project component engineering predictive computing entity 214. In some embodiments, the cloud-based project operations device 140 is configured to generate a new physical component object 412 in response to generating a physical component generation indicator 410. In this regard, in some embodiments, the cloud-based project operations device 140 is configured to generate a new physical component object 412 based on a physical component generation indicator 410.

In some embodiments, a new physical component object 412 comprises one or more items of data that describes a physical component that may be implemented in a proposed project associated with a requirement electronic record 406 and does not correspond to a physical component associated with at least one of the set of archived physical component objects (e.g., a new physical component object 412 is associated with a new physical component). In this regard, in some embodiments, a new physical component object may describe a physical component that satisfies a physical component feature associated with a requirement electronic record 406. For example, a new physical component object 412 may describe an HVAC unit having a volume that is within a particular range of acceptable volumes. In some embodiments, the new physical component object 412 comprises a 3-dimensional virtual model that depicts a physical component that may be implemented in a proposed project associated with a requirement electronic record 406.

As shown in block 710, the method 700 may comprise extracting, using the project component engineering predictive computing entity, a set of new physical component features from the new physical component object. As described above, in some embodiments, the cloud-based project operations device 140 is configured to extract a set of new physical component features 414 from a new physical component object 412. For example, the cloud-based project operations device 140 is configured to extract a set of new physical component features from a new physical component object 412 using the project component engineering predictive computing entity 214. In some embodiments, a new physical component feature comprises one or more items of data representative of one or more subsidiary components of a physical component represented by a new physical component object 412. For example, the set of new physical component features 414 may be representative of screws, circuity, enclosures, condensers, fans, and/or the like of an HVAC unit. Said differently, for example, the set of new physical component features 414 may be representative of the materials and/or components that make of a physical component represented by a new physical component object 412 (e.g., a bill of materials). In this regard, in some embodiments, the new physical component object 412 comprises a 3-dimensional virtual model that depicts a set of new physical component features 414 of a physical component that may be implemented in a proposed project associated with a requirement electronic record 406.

As shown in block 712, the method 700 may comprise causing, using the project orchestration predictive computing entity, performance of one or more new physical component responsive actions based on at least one of the set of new physical component features. As described above, in some embodiments, the cloud-based project operations device 140 is configured to cause performance of one or more new physical component responsive actions 416. For example, the cloud-based project operations device 140 is configured to cause performance of one or more new physical component responsive actions 416 using the project orchestration predictive computing entity 204. In some embodiments, the cloud-based project operations device 140 is configured to cause performance of one or more new physical component responsive actions 416 based on the new physical component object 412. In some embodiments, the cloud-based project operations device 140 is configured to cause performance of one or more new physical component responsive actions 416 based on the set of new physical component features 414 associated with the new physical component object 412. In this regard, in some embodiments, causing performance of one or more new physical component responsive actions comprises the cloud-based project operations device 140 being configured to generate one or more project electronic records. For example, the cloud-based project operations device 140 may be configured to generate one or more project electronic records using the project orchestration predictive computing entity 204 and/or the project record predictive computing entity 212. In this regard, in some embodiments, a project electronic record may comprise a plan, design, and/or process for implementing the proposed project corresponding to a requirement electronic record 406 using the new physical component object 412. For example, a project electronic record may comprise a plan, design, and/or process for implementing the proposed project corresponding to a requirement electronic record 406 that describes how to configure a set of new physical component features 414 in order to implement a physical component associated with the new physical component object 412 in the proposed project.

In some embodiments, causing performance of one or more new physical component responsive actions 416 comprises the project component engineering predictive computing entity 214 being configured to generate a project electronic record interface component 602. In some embodiments, the project electronic record interface component 602 is configured to display a visual representation 604 of one or more project electronic records. For example, the visual representation 604 may be a representation of a project electronic record that comprises a plan, design, and/or process for implementing the proposed project corresponding to a requirement electronic record 406 using the new physical component object 412. In some embodiments, causing performance of one or more new physical component responsive actions 416 comprises the cloud-based project operations device 140 being configured to cause a project electronic record interface component 602 to be rendered to responsive action interface 600. In some embodiments, the responsive action interface 600 may be provided on a display associated with the cloud-based project operations device 140 and/or a display associated with the project foundation device 180.

In some embodiments, causing performance of one or more new physical component responsive actions 416 comprises the cloud-based project operations device 140 being configured to cause a component inventory record to be updated. In some embodiments, a component inventory record is a record that indicates one or more new physical components that may be included in a project associated with a project electronic record (e.g., a project electronic record comprising the new physical component object 412). In this regard, for example, a component inventory record may be updated to be associated with an indication that a new physical component is necessary for the manufacturing of a project component associated with a project electronic record. As another example, a component inventory record may be updated to cause, by cloud-based project operations device 140 via inventory predictive computing entity 206, procurement of a new physical component. In this regard, in some embodiments, causing performance of one or more new physical component responsive actions 416 may comprise causing one or more manufacturing systems to operate in order to generate a new physical component (e.g., a new physical component associated with the new physical component object 412). Additionally, or alternatively, causing performance of one or more new physical component responsive actions 416 may comprise causing one or more systems to shut down (e.g., after the new physical component has been generated).

In some embodiments, causing performance of one or more new physical component responsive actions 416 comprises the cloud-based project operations device 140 being configured to transmit a project electronic record to the project foundation device 180. For example, when a project electronic record is generated, the cloud-based project operations device 140 may be configured to transmit the project electronic record to the project foundation device 180 indicating that project electronic record (e.g., a project electronic record comprising the new physical component object 412) has been generated based on a requirement electronic record 406 by the cloud-based project operations device 140.

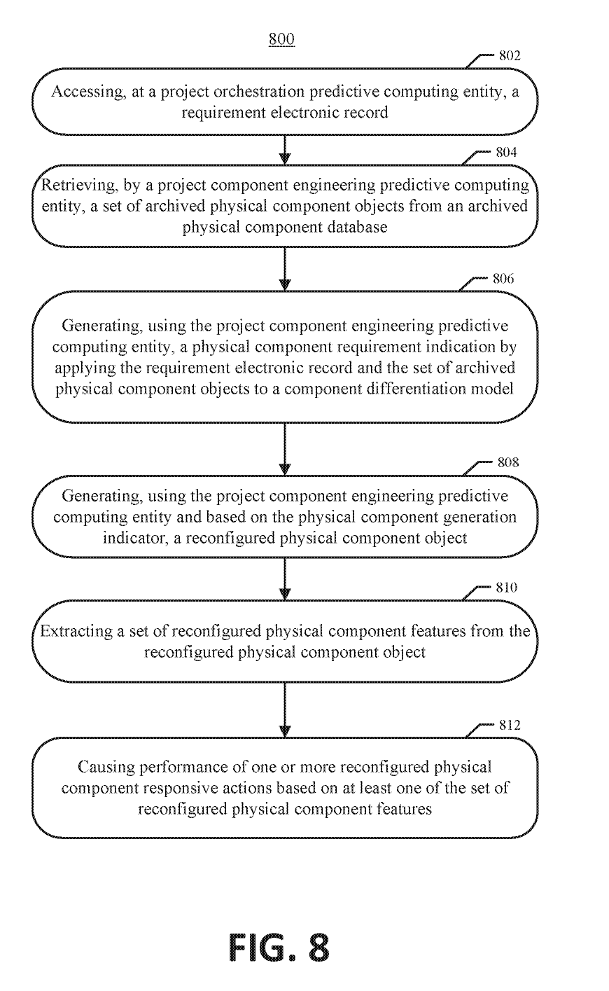

Referring now to FIG. 8, a flowchart providing an example method 800 is illustrated. In this regard, FIG. 8 illustrates operations that may be performed by the project foundation device 180, the external project implementation device 120, the external project application device 110, the cloud-based project operations device 140, the one or more databases 150, and/or the user device 170. In some embodiments, the method 800 comprises operations for generating a reconfigured physical component object. In some embodiments, the example method 800 defines a computer-implemented process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 800.

As shown in block 802, the method 800 may comprise accessing, at a project orchestration predictive computing entity, a requirement electronic record. In some embodiments, the requirement electronic record is representative of a physical component feature. As described above, in some embodiments, a physical component feature comprises one or more items of data representative of a requirement, a criteria, and/or a constraint associated with a physical component to be used in a proposed project that must be satisfied in order to implement a proposed project. For example, a physical component feature may be one or more items of data that are representative of a requirement, a criteria, and/or a constraint associated with a physical component to be used in a proposed project that must be satisfied in order to implement a proposed project that includes controlling the temperature of a building. In this regard, for example, a physical component feature may be representative of a maximum surface area (e.g., a constraint, a criteria, and/or a requirement) of a circuit board (e.g., a physical component) to be used in a proposed project that must be satisfied in order for the proposed project to be implemented. As another example, a physical component feature may be representative of a particular range of acceptable volumes (e.g., a constraint, a criteria, and/or a requirement) of an HVAC unit (e.g., a physical component) to be used in a proposed project that must be satisfied in order for the proposed project to be implemented.

As shown in block 804, the method 800 may comprise retrieving, by a project component engineering predictive computing entity, a set of archived physical component objects from an archived physical component database. As described above, in some embodiments, a physical component feature comprises one or more items of data representative of a requirement, a criteria, and/or a constraint associated with a physical component to be used in a proposed project that must be satisfied in order to implement a proposed project. For example, a physical component feature may be one or more items of data that are representative of a requirement, a criteria, and/or a constraint associated with a physical component to be used in a proposed project that must be satisfied in order to implement a proposed project that includes controlling the temperature of a building. In this regard, for example, a physical component feature may be representative of a maximum surface area (e.g., a constraint, a criteria, and/or a requirement) of a circuit board (e.g., a physical component) to be used in a proposed project that must be satisfied in order for the proposed project to be implemented. As another example, a physical component feature may be representative of a particular range of acceptable volumes (e.g., a constraint, a criteria, and/or a requirement) of an HVAC unit (e.g., a physical component) to be used in a proposed project that must be satisfied in order for the proposed project to be implemented.

As shown in block 806, the method 800 may comprise generating, using the project component engineering predictive computing entity, a physical component requirement indication by applying the requirement electronic record and the set of archived physical component objects to a component differentiation model. In some embodiments, the physical component requirement indication comprises a physical component generation indicator or a physical component reconfiguration indicator.

As described above, in some embodiments, the cloud-based project operations device 140 is configured to generate a physical component requirement indication. For example, the cloud-based project operations device 140 may be configured to generate a physical component requirement indication using the project component engineering predictive computing entity 214. In some embodiments, the cloud-based project operations device 140 is configured to generate a physical component requirement indication based on a requirement electronic record 406 and/or at least one of a set of archived physical component objects 408. In some embodiments, a physical component requirement indication comprises a physical component generation indicator 410. Additionally, or alternatively, a physical component requirement indication comprises a physical component reconfiguration indicator. Said differently, for example, a physical component requirement indication may be a physical component generation indicator or a physical component reconfiguration indicator. In some embodiments, a physical component generation indicator 410 comprises one or more items of data that indicates that the set of archived physical component objects 408 does not include an archived physical component object that may be used to satisfy a physical component feature associated with a requirement electronic record 406. In this regard, for example, a physical component generation indicator 410 may indicate that the set of archived physical component objects 408 does not include an archived physical component object that satisfies a requirement, a criteria, and/or a constraint associated with a physical component to be used in a proposed project that must be satisfied in order to implement a proposed project. For example, a physical component generation indicator 410 may indicate that the set of archived physical component objects 408 does not include an archived physical component object representative of an HVAC unit having a volume that is within a particular range of acceptable volumes. Said differently, for example, a physical component generation indicator 410 may indicate that the set of archived physical component objects 408 does not include an archived physical component that describes a completed, previous, and/or archived physical component that may be used to satisfy a physical component feature associated with a requirement electronic record 406.

In some embodiments, the cloud-based project operations device 140 is configured to generate a physical component generation indicator 410 based on a requirement electronic record 406 and/or at least one of a set of archived physical component objects 408 (e.g., using the project component engineering predictive computing entity 214). For example, the cloud-based project operations device 140 may be configured to generate a physical component generation indicator 410 by applying a requirement electronic record 406 and/or at least one of a set of archived physical component objects 408 to a component differentiation model 404. In this regard, in some embodiments, the component differentiation model 404 may be configured to generate a physical component generation indicator 410 by comparing a requirement electronic record 406 and at least one of a set of archived physical component objects 408.

As shown in block 808, the method 800 may comprise generating, based on the physical component reconfiguration indicator, a reconfigured physical component object. In some embodiments, the reconfigured physical component object corresponds to an archived physical component object of the set of archived physical component objects.

As described above, in some embodiments, the cloud-based project operations device 140 is configured to generate a reconfigured physical component object 512. For example, the cloud-based project operations device 140 may be configured to generate a reconfigured physical component object 512 using the project component engineering predictive computing entity 214. In some embodiments, the cloud-based project operations device 140 is configured to generate a reconfigured physical component object 512 in response to generating a physical component reconfiguration indicator 510. In this regard, in some embodiments, the cloud-based project operations device 140 is configured to generate a reconfigured physical component object 512 based on a physical component reconfiguration indicator 510.

In some embodiments, a reconfigured physical component object 512 comprises one or more items of data that describes a physical component that may be implemented in a proposed project associated with a requirement electronic record 406 and corresponds to a physical component associated with at least one of the set of archived physical component objects (e.g., a reconfigured physical component object 512 is associated with a reconfigured version of a physical component associated with at least one of the set of archived physical component objects). In this regard, in some embodiments, a reconfigured physical component object 512 may describe a physical component that satisfies a physical component feature associated with a requirement electronic record 406. For example, a reconfigured physical component object 512 may describe an HVAC unit that has been reconfigured to have a volume that is within a particular range of acceptable volumes. In some embodiments, the reconfigured physical component object 512 comprises a 3-dimensional virtual model that depicts a physical component that may be implemented in a proposed project associated with a requirement electronic record 406.

As shown in block 810, the method 800 may comprise extracting a set of reconfigured physical component features from the reconfigured physical component object. As described above, in some embodiments, the cloud-based project operations device 140 is configured to extract a set of reconfigured physical component features 514 from a reconfigured physical component object 512. For example, the cloud-based project operations device 140 is configured to extract a set of reconfigured physical component features 514 from a reconfigured physical component object 512 using the project component engineering predictive computing entity 214. In some embodiments, a reconfigured physical component feature comprises one or more items of data representative of one or more subsidiary components of a physical component represented by a reconfigured physical component object 512. For example, the set of reconfigured physical component features 514 may be representative of screws, circuity, enclosures, condensers, fans, and/or the like of an HVAC unit that has been reconfigured in order to be implemented in a proposed project. Said differently, for example, the set of reconfigured physical component features 514 may be representative of the materials and/or components that make of a physical component represented by a reconfigured physical component object 512 (e.g., a bill of materials). In this regard, in some embodiments, the reconfigured physical component object 512 comprises a 3-dimensional virtual model that depicts a set of reconfigured physical component features 514 of a physical component that may be implemented in a proposed project associated with a requirement electronic record 406.

As shown in block 812, the method 800 may comprise causing performance of one or more reconfigured physical component responsive actions based on at least one of the set of reconfigured physical component features. As described above, in some embodiments, the cloud-based project operations device 140 is configured to cause performance of one or more reconfigured physical component responsive actions 516. For example, the cloud-based project operations device 140 is configured to cause performance of one or more reconfigured physical component responsive actions 516 using the project orchestration predictive computing entity 204. In some embodiments, the cloud-based project operations device 140 is configured to cause performance of one or more reconfigured physical component responsive actions 516 based on the reconfigured physical component object 512. In some embodiments, the cloud-based project operations device 140 is configured to cause performance of one or more reconfigured physical component responsive actions 516 based on the set of reconfigured physical component features 514 associated with the reconfigured physical component object 512. In this regard, in some embodiments, causing performance of one or more reconfigured physical component responsive actions 516 comprises the cloud-based project operations device 140 being configured to generate one or more project electronic records. For example, the cloud-based project operations device 140 may be configured to generate one or more project electronic records using the project orchestration predictive computing entity 204 and/or the project record predictive computing entity 212. In this regard, in some embodiments, a project electronic record may comprise a plan, design, and/or process for implementing the proposed project corresponding to a requirement electronic record 406 using the reconfigured physical component object 512. For example, a project electronic record may comprise a plan, design, and/or process for implementing the proposed project corresponding to a requirement electronic record 406 that describes how to configure a set of reconfigured physical component features 514 in order to implement a physical component associated with the reconfigured physical component object 512 in the proposed project.

In some embodiments, causing performance of one or more reconfigured physical component responsive actions 516 comprises the project component engineering predictive computing entity 214 being configured to generate a project electronic record interface component 602. In some embodiments, the project electronic record interface component 602 is configured to display a visual representation 604 of one or more project electronic records. For example, the visual representation 604 may be a representation of a project electronic record that comprises a plan, design, and/or process for implementing the proposed project corresponding to a requirement electronic record 406 using the reconfigured physical component object 512. In some embodiments, causing performance of one or more reconfigured physical component responsive actions 516 comprises the cloud-based project operations device 140 being configured to cause a project electronic record interface component 602 to be rendered to responsive action interface 600. In some embodiments, the responsive action interface 600 may be provided on a display associated with the cloud-based project operations device 140 and/or a display associated with the project foundation device 180.

In some embodiments, causing performance of one or more reconfigured physical component responsive actions 516 comprises the cloud-based project operations device 140 being configured to cause a component inventory record to be updated. In some embodiments, a component inventory record is a record that indicates one or more reconfigured physical components that may be included in a project associated with a project electronic record (e.g., a project electronic record comprising the reconfigured physical component object 512). In this regard, for example, a component inventory record may be updated to be associated with an indication that a reconfigured physical component is necessary for the manufacturing of a project component associated with a project electronic record. As another example, a component inventory record may be updated to cause, by cloud-based project operations device 140 via inventory predictive computing entity 206, procurement of a reconfigured physical component. In this regard, in some embodiments, causing performance of one or more reconfigured physical component responsive actions 516 may comprise causing one or more manufacturing systems to operate in order to generate a reconfigured physical component (e.g., a reconfigured physical component associated with the reconfigured physical component object 512). Additionally, or alternatively, causing performance of one or more reconfigured physical component responsive actions 516 may comprise causing one or more systems to shut down (e.g., after the reconfigured physical component has been generated).

In some embodiments, causing performance of one or more reconfigured physical component responsive actions 516 comprises the cloud-based project operations device 140 being configured to transmit a project electronic record to the project foundation device 180. For example, when a project electronic record is generated, the cloud-based project operations device 140 may be configured to transmit the project electronic record to the project foundation device 180 indicating that project electronic record (e.g., a project electronic record comprising the reconfigured physical component object 512) has been generated based on a requirement electronic record 406 by the cloud-based project operations device 140.

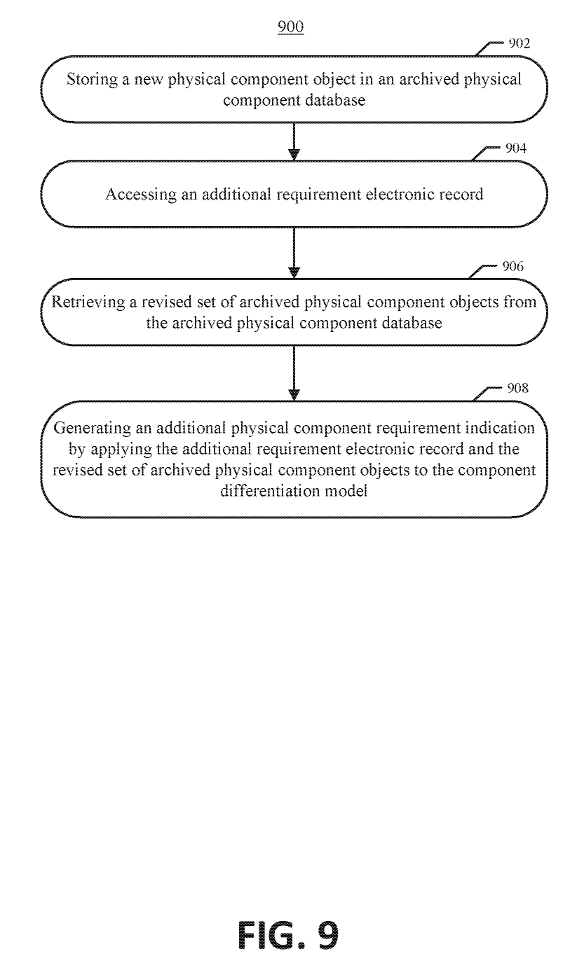

Referring now to FIG. 9, a flowchart providing an example method 900 is illustrated. In this regard, FIG. 9 illustrates operations that may be performed by the project foundation device 180, the external project implementation device 120, the external project application device 110, the cloud-based project operations device 140, the one or more databases 150, and/or the user device 170. In some embodiments, the method 900 comprises operations for generating an additional physical component requirement indication. In some embodiments, the example method 900 defines a computer-implemented process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 900.

As shown in block 902, the method 900 may comprise storing the new physical component object in the archived physical component database. As described above, in some embodiments, the cloud-based project operations device 140 is configured to store the new physical component object 412 in the archived physical component database 402. For example, the cloud-based project operations device 140 may be configured to store the new physical component object 412 in the archived physical component database 402 using the project orchestration predictive computing entity 204 and/or the project component engineering predictive computing entity 214. In some embodiments, by storing the new physical component object 412 in the archived physical component database 402 the cloud-based project operations device 140 is configured to generate a revised set of archived physical component objects 420. In some embodiments, the revised set of archived physical component objects 420 comprises the new physical component object 412 and/or the set of archived physical component objects 408. In this regard, for example, the new physical component object 412 may be used for responding to other requirement electronic records.

As shown in block 904, the method 900 may comprise accessing an additional requirement electronic record. In some embodiments, the additional requirement electronic record is representative of an additional physical component feature.

As described above, in some embodiments, the cloud-based project operations device 140 is configured to access an additional requirement electronic record 418. For example, the cloud-based project operations device 140 may be configured to access the additional requirement electronic record 418 at the project orchestration predictive computing entity 204 (e.g., the cloud-based project operations device 140 is configured to access the additional requirement electronic record 418 using the project orchestration predictive computing entity 204). In some embodiments, an additional requirement electronic record 418 comprises an additional physical component feature. In some embodiments, an additional physical component feature comprises one or more items of data representative of a requirement, a criteria, and/or a constraint associated with a physical component to be used in an additional proposed project that must be satisfied in order to implement an additional proposed project. Said differently, for example, additional requirement electronic record 418 may have a similar structure and/or form as a requirement electronic record 406 but corresponds to a different proposed project than the requirement electronic record 406. In this regard, for example, the cloud-based project operations device 140 may be configured to access the additional requirement electronic record 418 after the cloud-based project operations device 140 has caused performance of one or more new physical component responsive actions 416 and/or one or more reconfigured physical component responsive actions 516.

As shown in block 906, the method 900 may comprise retrieving a revised set of archived physical component objects from the archived physical component database. In some embodiments, the revised set of archived physical component objects comprises the new physical component object.

As described above, in some embodiments, the cloud-based project operations device 140 is configured to retrieve the revised set of archived physical component objects 420 from the archived physical component database 402. For example, the cloud-based project operations device 140 may be configured to retrieve the revised set of archived physical component objects 420 from the archived physical component database 402 using the project component engineering predictive computing entity 214.

As shown in block 908, the method 900 may comprise generating an additional physical component requirement indication by applying the additional requirement electronic record and the revised set of archived physical component objects to the component differentiation model. In some embodiments, the additional physical component requirement indication comprises an additional physical component generation indicator, an additional physical component reconfiguration indicator 522, or a physical component reusable indicator.

As described above, in some embodiments, the cloud-based project operations device 140 is configured to generate an additional physical component requirement indication. For example, the cloud-based project operations device 140 may be configured to generate an additional physical component requirement indication using the project component engineering predictive computing entity 214. In some embodiments, the cloud-based project operations device 140 is configured to generate an additional physical component requirement indication based on an additional requirement electronic record 418 and/or at least one of the revised set of archived physical component objects 420.

In some embodiments, an additional physical component requirement indication comprises an additional physical component generation indicator. In some embodiments, an additional physical component generation indicator comprises one or more items of data that indicates that the revised set of archived physical component objects 420 does not include an archived physical component object that may be used to satisfy an additional physical component feature associated with the additional requirement electronic record 418 and that the new physical component object 412 cannot be used to satisfy an additional physical component feature associated with the additional requirement electronic record 418. Said differently, for example, an additional physical component generation indicator may be similar to a physical component generation indicator but correspond to the additional requirement electronic record 418 rather than the requirement electronic record 406.

In some embodiments, an additional physical component requirement indication comprises an additional physical component reconfiguration indicator 522. In some embodiments, an additional physical component reconfiguration indicator 522 comprises one or more items of data that indicates that the revised set of archived physical component objects 420 includes an archived physical component object representative of a physical component that may be reconfigured such that it may be used to satisfy an additional physical component feature associated with the additional requirement electronic record 418 and/or that the new physical component object 412 may be reconfigured to be used to satisfy an additional physical component feature associated with the additional requirement electronic record 418. Said differently, for example, an additional physical component reconfiguration indicator 522 may be similar to a physical component reconfiguration indicator but correspond to the additional requirement electronic record 418 rather than the requirement electronic record 406.

In some embodiments, an additional physical component requirement indication comprises a physical component reusable indicator 422. In some embodiments, a physical component reusable indicator 422 comprises one or more items of data that indicates that the new physical component object 412 in the revised set of archived physical component objects 420 may be used to satisfy an additional physical component feature associated with the additional requirement electronic record 418. Said differently, for example, an additional physical component requirement indication may be an additional physical component generation indicator, an additional physical component reconfiguration indicator 522, and/or a physical component reusable indicator 422.

In some embodiments, the cloud-based project operations device 140 is configured to generate an additional physical component requirement indication based on the additional requirement electronic record 418 and/or at least one of the revised set of archived physical component objects 420 (e.g., using the project component engineering predictive computing entity 214). For example, the cloud-based project operations device 140 may be configured to generate an additional physical component requirement indication by applying the additional requirement electronic record 418 and/or at least one of the revised set of archived physical component objects 420 to a component differentiation model 404. In this regard, in some embodiments, the component differentiation model 404 may be configured to generate an additional physical component requirement indication by comparing the additional requirement electronic record 418 and at least one archived physical component object of the revised set of archived physical component objects 420.

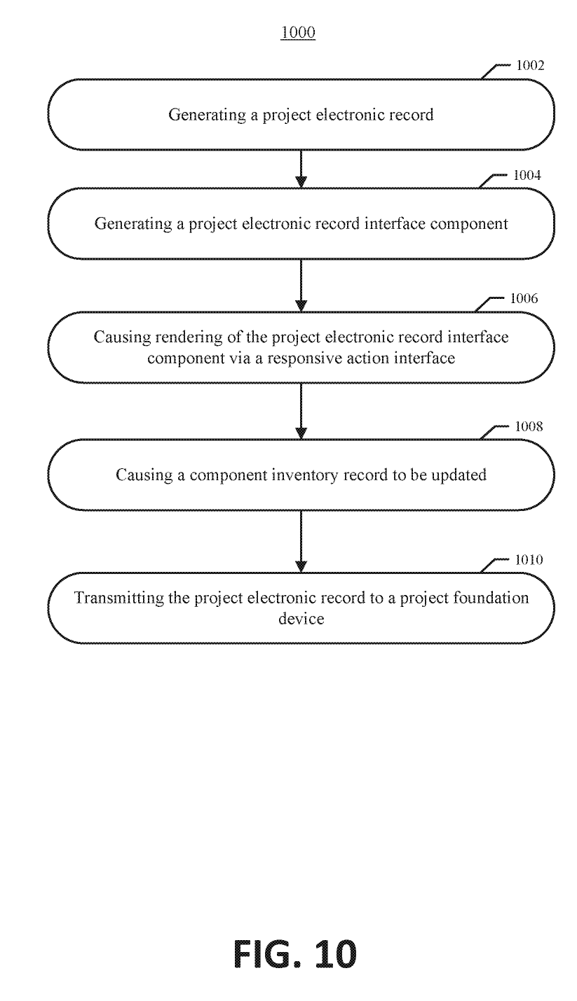

Referring now to FIG. 10, a flowchart providing an example method 1000 is illustrated. In this regard, FIG. 10 illustrates operations that may be performed by the project foundation device 180, the external project implementation device 120, the external project application device 110, the cloud-based project operations device 140, the one or more databases 150, and/or the user device 170. In some embodiments, the method 1000 comprises operations for causing performance of one or more physical component responsive actions based on at least one of the set of physical component features. In some embodiments, the example method 1000 defines a computer-implemented process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 1000.

As shown in block 1002, the method 1000 may comprise generating a project electronic record. In some embodiments, the project electronic record comprises the new physical component object. In some embodiments, the project electronic record comprises at least one of the set of reconfigured physical component features 514.

As described above, in some embodiments, causing performance of one or more new physical component responsive actions comprises the cloud-based project operations device 140 being configured to generate one or more project electronic records. For example, the cloud-based project operations device 140 may be configured to generate one or more project electronic records using the project orchestration predictive computing entity 204 and/or the project record predictive computing entity 212. In this regard, in some embodiments, a project electronic record may comprise a plan, design, and/or process for implementing the proposed project corresponding to a requirement electronic record 406 using the new physical component object 412. For example, a project electronic record may comprise a plan, design, and/or process for implementing the proposed project corresponding to a requirement electronic record 406 that describes how to configure a set of new physical component features 414 in order to implement a physical component associated with the new physical component object 412 in the proposed project.

As shown in block 1004, the method 1000 may comprise generating, a project electronic record interface component 602. In some embodiments, causing performance of one or more new physical component responsive actions 416 comprises the project component engineering predictive computing entity 214 being configured to generate a project electronic record interface component 602. In some embodiments, the project electronic record interface component 602 is configured to display a visual representation 604 of one or more project electronic records. For example, the visual representation 604 may be a representation of a project electronic record that comprises a plan, design, and/or process for implementing the proposed project corresponding to a requirement electronic record 406 using the new physical component object 412.

As shown in block 1006, the method 1000 may comprise causing rendering of the project electronic record interface component 602 via a responsive action interface 600. As described above, in some embodiments, causing performance of one or more new physical component responsive actions 416 comprises the cloud-based project operations device 140 being configured to cause a project electronic record interface component 602 to be rendered to responsive action interface 600. In some embodiments, the responsive action interface 600 may be provided on a display associated with the cloud-based project operations device 140 and/or a display associated with the project foundation device 180.

As shown in block 1008, the method 1000 may comprise causing a component inventory record to be updated. As described above, in some embodiments, causing performance of one or more new physical component responsive actions 416 comprises the cloud-based project operations device 140 being configured to cause a component inventory record to be updated. In some embodiments, a component inventory record is a record that indicates one or more new physical components that may be included in a project associated with a project electronic record (e.g., a project electronic record comprising the new physical component object 412). In this regard, for example, a component inventory record may be updated to be associated with an indication that a new physical component is necessary for the manufacturing of a project component associated with a project electronic record. As another example, a component inventory record may be updated to cause, by cloud-based project operations device 140 via inventory predictive computing entity 206, procurement of a new physical component. In this regard, in some embodiments, causing performance of one or more new physical component responsive actions 416 may comprise causing one or more manufacturing systems to operate in order to generate a new physical component (e.g., a new physical component associated with the new physical component object 412). Additionally, or alternatively, causing performance of one or more new physical component responsive actions 416 may comprise causing one or more systems to shut down (e.g., after the new physical component has been generated).

As shown in block 1010, the method 1000 may comprise transmitting the project electronic record to a project foundation device 180. As described above, in some embodiments, causing performance of one or more new physical component responsive actions 416 comprises the cloud-based project operations device 140 being configured to transmit a project electronic record to the project foundation device 180. For example, when a project electronic record is generated, the cloud-based project operations device 140 may be configured to transmit the project electronic record to the project foundation device 180 indicating that project electronic record (e.g., a project electronic record comprising the new physical component object 412) has been generated based on a requirement electronic record 406 by the cloud-based project operations device 140.

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a computer-implemented process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

Similarly, while operations are illustrated in the drawings in a particular order, this should not be understood as requiring that such operations be performed in the particular order shown or in sequential order, or that all illustrated operations be performed, to achieve desirable results. In certain circumstances, operations in alternative ordering may be advantageous. In some cases, the actions recited in the claims may be performed in a different order and still achieve desirable results.

1. A method comprising:
accessing, at a project orchestration predictive computing entity, a requirement electronic record, wherein the requirement electronic record is representative of a physical component feature;
retrieving, by a project component engineering predictive computing entity, a set of archived physical component objects from an archived physical component database;
generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator;
generating, using the project component engineering predictive computing entity and based on the physical component generation indicator, a new physical component object;
extracting, using the project component engineering predictive computing entity, a set of new physical component features from the new physical component object; and
causing, using the project orchestration predictive computing entity, performance of one or more new physical component responsive actions based on at least one of the set of new physical component features.

2. The method of claim 1, further comprising:
generating, based on the physical component reconfiguration indicator, a reconfigured physical component object, wherein the reconfigured physical component object corresponds to an archived physical component object of the set of archived physical component objects;
extracting a set of reconfigured physical component features from the reconfigured physical component object; and
causing performance of one or more reconfigured physical component responsive actions based on at least one of the set of reconfigured physical component features.

3. The method of claim 1, wherein the new physical component object comprises a 3-dimensional virtual model.

4. The method of claim 1, further comprising:
storing the new physical component object in the archived physical component database;
accessing an additional requirement electronic record, wherein the additional requirement electronic record is representative of an additional physical component feature;
retrieving a revised set of archived physical component objects from the archived physical component database, wherein the revised set of archived physical component objects comprises the new physical component object; and
generating an additional physical component requirement indication by applying the additional requirement electronic record and the revised set of archived physical component objects to the component differentiation model, wherein the additional physical component requirement indication comprises an additional physical component generation indicator, an additional physical component reconfiguration indicator, or a physical component reusable indicator.

5. The method of claim 4, further comprising:
generating, based on the physical component reusable indicator, an additional project electronic record, wherein the additional project electronic record comprises the new physical component object.

6. The method of claim 4, further comprising:
generating, based on the physical component reconfiguration indicator, an additional project electronic record, wherein the additional project electronic record comprises an additional reconfigured physical component object.

7. The method of claim 1, wherein causing performance of the one or more new physical component responsive actions comprises:
generating a project electronic record, wherein the project electronic record comprises the new physical component object.

8. The method of claim 7, wherein causing performance of the one or more new physical component responsive actions comprises:
generating, a project electronic record interface component, wherein the project electronic record interface component comprises a visual representation of the project electronic record; and
causing rendering of the project electronic record interface component via a responsive action interface.

9. The method of claim 1, wherein causing performance of the one or more new physical component responsive actions comprises:
causing a component inventory record to be updated.

10. The method of claim 7, wherein causing performance of the one or more new physical component responsive actions comprises:
transmitting the project electronic record to a project foundation device.

11. An apparatus comprising memory and one or more processors communicatively coupled to the memory, the one or more processors configured to perform operations comprising:
accessing, at a project orchestration predictive computing entity, a requirement electronic record, wherein the requirement electronic record is representative of a physical component feature;
retrieving, by a project component engineering predictive computing entity, a set of archived physical component objects from an archived physical component database;
generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator;
generating, using the project component engineering predictive computing entity and based on the physical component generation indicator, a new physical component object;
extracting, using the project component engineering predictive computing entity, a set of new physical component features from the new physical component object; and
causing, using the project orchestration predictive computing entity, performance of one or more new physical component responsive actions based on at least one of the set of new physical component features.

12. The apparatus of claim 11, wherein the one or more processors are further configured to perform operations comprising:
generating, based on the physical component reconfiguration indicator, a reconfigured physical component object, wherein the reconfigured physical component object corresponds to an archived physical component object of the set of archived physical component objects;
extracting a set of reconfigured physical component features from the reconfigured physical component object; and
causing performance of one or more reconfigured physical component responsive actions based on at least one of the set of reconfigured physical component features.

13. The apparatus of claim 11, wherein causing performance of the one or more new physical component responsive actions comprises:
generating a project electronic record, wherein the project electronic record comprises the new physical component object.

14. The apparatus of claim 13, wherein causing performance of the one or more new physical component responsive actions further configures the one or more processors to perform operations comprising:
generating, a project electronic record interface component, wherein the project electronic record interface component comprises a visual representation of the project electronic record; and
causing rendering of the project electronic record interface component via a responsive action interface.

15. The apparatus of claim 11, wherein the one or more processors are further configured to perform operations comprising:
causing a component inventory record to be updated.

16. A computer program product comprising at least one non-transitory computer-readable storage medium having computer program code stored thereon that, in execution with at least one processor, configures the computer program product for:
accessing, at a project orchestration predictive computing entity, a requirement electronic record, wherein the requirement electronic record is representative of a physical component feature;
retrieving, by a project component engineering predictive computing entity, a set of archived physical component objects from an archived physical component database;
generating, using the project component engineering predictive computing entity, a physical component requirement indication by applying the requirement electronic record and the set of archived physical component objects to a component differentiation model, wherein the physical component requirement indication comprises a physical component generation indicator or a physical component reconfiguration indicator;
generating, using the project component engineering predictive computing entity and based on the physical component generation indicator, a new physical component object;
extracting, using the project component engineering predictive computing entity, a set of new physical component features from the new physical component object; and
causing, using the project orchestration predictive computing entity, performance of one or more new physical component responsive actions based on at least one of the set of new physical component features.

17. The computer program product of claim 16, wherein computer program code, in execution with at least one processor, further configures the computer program product for:
generating, based on the physical component reconfiguration indicator, a reconfigured physical component object, wherein the reconfigured physical component object corresponds to an archived physical component object of the set of archived physical component objects;
extracting a set of reconfigured physical component features from the reconfigured physical component object; and
causing performance of one or more reconfigured physical component responsive actions based on at least one of the set of reconfigured physical component features.

18. The computer program product of claim 16, wherein causing performance of the one or more new physical component responsive actions comprises:
generating a project electronic record, wherein the project electronic record comprises the new physical component object.

19. The computer program product of claim 18, wherein causing performance of the one or more new physical component responsive actions further configures the computer program code, in execution with at least one processor, to configure the computer program product for:
generating, a project electronic record interface component, wherein the project electronic record interface component comprises a visual representation of the project electronic record; and
causing rendering of the project electronic record interface component via a responsive action interface.

20. The computer program product of claim 16, wherein computer program code, in execution with at least one processor, further configures the computer program product for:
causing a component inventory record to be updated.
